(19) United States
(12) Patent Application Publication
(10) Pub. No.: US 2003/0203624 A1
(43) Pub. Date: Oct. 30, 2003

(54) Manufacturing method of semiconductor device

(76) Inventors: Kenji Sameshima, Hachioji (JP); Yoshio Homma, Hinode (JP); Noriyuki Sakuma, Hachioji (JP)

Correspondence Address: Mattingly, Stanger & Malur, P.C., Suite 370, 1800 Diagonal Road, Alexandria, VA, 22314, US

(21) Appl. No.: 10/394,051

(22) Filed: Mar. 24, 2003

(30) Foreign Application Priority Data
Mar. 27, 2002 (JP) 2002-087398
Dec. 27, 2002 (JP) 2002-378951

(51) Int. Cl. H01L 21/4763; H01L 21/44; H01L 21/302; H01L 21/461

(52) U.S. Cl. 438/687; 438/693; 438/629; 438/692

(57) ABSTRACT

Protection film excellent in protection characteristics and easily removed by mechanical friction, is formed by enabling CMP at high rate for copper or copper-based alloy while suppressing polishing scratches, delamination, dishing and erosion, particularly, enabling CMP for copper or copper-based alloy on an easily delaminating low dielectric constant insulation film, and using plural corrosion inhibitors, for example, BTA and imidazole together in an abrasive-free polishing solution.

manufacturing method referred to as a damascene method has been used mainly (refer to, for example, to Japanese Patent Laid-open No. 2-278822). In the manufacturing method of wiring using the damascene method, a barrier layer intended both for enhancing the adhesion and anti-diffusion of copper or copper-based alloy layer and a copper or copper-based alloy layer for wiring are formed successively on an insulative film comprising a laminate film, for example, of silicon oxide (hereinafter referred to as SiO₂) and silicon nitride (hereinafter referred to as SiN) formed with via holes or wiring trenches (hereinafter collectively referred to as trenches) and buried in the trenches.

The SiN layer is used as an etching stopper from which a portion necessary for connection with the lower level wiring is selectively removed. Titanium, tungsten, tantalum or nitrogen compounds or silicon nitrogen compounds of about 10 to 50 nm is mainly used as the barrier layer. Further, for the insulative film, insulation film with a lower specific dielectric constant compared with Sio₂ or SiN has now been started for use instead of SiO₂ or SiN in LSI (hereinafter referred to as low-k film). This is used for reducing the static capacitance between wiring (hereinafter referred to as capacitance) thereby decreasing the delay of signals passing through the wiring and thus improving the performance of LSI. Fluoro-containing silicon oxide (hereinafter referred to as fluorinated SiO₂, FSG), silicon carbide (hereinafter referred to as SiC) and the like are used as the low-k film. FSG has a merit that the mechanical property is substantially similar to that of SiO₂ and conventional LSI production technique can be applied. SiC is used instead of SiN. A method of using electrolytic etching instead of CMP to the low-k film has been proposed (refer, for example, to proceedings IEDM 2001, 4.4.1-4.4.4 pp 84-87). The polishing solution used for CMP of the metal films generally comprises polishing abrasive grains and an oxidizer as the main ingredient. For the mechanism of CMP, it is described that oxides on the surface of the metal films are mechanically scraped off by abrasive grains during oxidization of the film surfaces as reported in a case of CMP for tungsten (for example, in J. Electrochem. Soc., Vol. 138, No. 11, November 1991, pp 3460-3464). A corrosion inhibitor is sometimes added to the polishing solution in CMP for easily erosible metals such as copper or copper-based alloy as will be described later. An alumina powder or silica powder having a grain size of several tens to several hundreds nm are used as abrasive grains. Hydrogen peroxide (usually at 30 wt % concentration in commercial products), ferric nitrate, or potassium periodate can be used as the oxidizer and, among all, aqueous hydrogen peroxide has been used generally since it contains no metal ions. The problem inherent to the abrasive-incorporated polishing solution includes that scratches tend to be formed during CMP. This is probably attributable to agglomeration of abrasive grains in the polishing solution into abnormally large grains, or localization of stresses caused by deviation of abrasive concentration during CMP.

Further, a new polishing method of metal films, particularly, of copper or copper-based alloy includes a damascene wiring technique using an abrasive-free polishing solution (hereinafter referred to as abrasive-free polishing solution) (refer, for example, to Japanese Patent Laid-open No. 11-135466: paragraphs [0008] and [0009]). CMP is conducted by mechanical friction of the surface of a metal film by using a polishing solution containing an oxidizer, a chemical solution for rendering oxides water soluble (refer to as an etchant), water and a chemical solution forming a protection film to the oxidizer on the surface of copper or copper-based alloy (hereinafter referred to as a protection film forming agent). In CMP for copper or copper-based alloy, BTA is used as a corrosion inhibitor. Since a polishing rate is also lowered although the etching rate can be suppressed by adding BTA, it is not desirable to excessively increase the BTA concentration. That is, the concentration and the type of the etchant and oxidizer are selected such that a high CMP rate can be obtained while keeping the concentration of BTA as low as possible within a range capable of sufficiently suppressing the etching rate for copper or copper-based alloy. An example is a polishing solution containing aqueous hydrogen peroxide, citric acid and BTA. It has a feature capable of polishing copper or copper-based alloy with high-accuracy while scarcely polishing the insulation film or the barrier film. The protection film forming agent in the polishing solution is deposited on the surface of a copper or copper-based alloy film to form a protection film thereby suppressing the copper or copper-based alloy film from being etched by the oxidizer or the etchant in the polishing solution. When a polishing pad is pressed on the surface of a copper or copper-based alloy film and protrusions of the copper or copper-based alloy film are scrubbed, the protection film is removed and the surface of copper or copper-based alloy is oxidized and the oxide layer is removed by the etchant. It is considered that planarization proceeds through the process described above. In the abrasive-free CMP, the CMP rate depends on the rate at which the protection film is scraped by the polishing pad and a rate at which the copper or copper-based alloy film is etched by the oxidizer or the etchant. As both of them are larger, the polishing rate is also higher.

On the other hand, the criterion for judging the adequacy for the result of CMP includes dishing and erosion. Dishing means a phenomenon that the surface of a metal film such as of copper or copper-based alloy forms a concaved shape like a dish compared with the surface of the insulation film at the periphery in the groove. It is considered that dishing mainly depends on the chemical effect of the polishing solution and, particularly, depends on the etching speed. Erosion means a phenomenon that the insulation film itself is scraped by CMP and this depends mainly on the effect of mechanical scraping of abrasive grains.

To attain copper or copper-based alloy wiring with high-accuracy by CMP, it is necessary to conduct CMP at a sufficient CMP rate and with less dishing or erosion. In particular, it is most important to use a polishing solution with the etching rate being suppressed in order to suppress dishing. The thickness of the copper or copper-based alloy film to which the present invention is applied is, at most, several μm and the thickness of the copper or copper-based alloy wiring layer formed by CMP is generally 1 μMm or less. Further, dishing on the surface of the copper or copper-based alloy film after CMP is desirably suppressed to 10% or less and, more preferably, 5% or less in the wiring thickness. In a case where the thickness of the copper or copper-based alloy wiring is about 500 nm, it is necessary to restrict the dishing depth to about 25-50 nm. In order not to cause polishing residue over the entire LSI surface, polishing has to be conducted excessively for about 20 to 30% of time. Further, the etching rate for the copper or copper-based alloy by the polishing solution has to be 10 nm/min or less while taking the scattering of the CMP rate in the CMP step itself into consideration. It is necessary to attain the characteristics of, preferably, 5 nm/min or less and, more preferably, 3 nm/min or less. The etching rate can be determined by dipping a copper or copper-based alloy film in a polishing solution under stirring or vibration and measuring the decrease in the thickness of the film per unit time. The concentration of the protection film forming agent, the etchant and the oxidizer has to be optimized so as to obtain a high CMP rate within a range capable of suppressing the etching rate to a predetermined value or less.

In the CMP using the abrasive-free polishing solution, the protection film forming agent, particularly, the corrosion inhibitor has an important role in various factors of CMP such as dishing property, corrosive property and the CMP rate. BTA is a typical material as the protection film forming agent for the copper or copper-based alloy. While it is desirable to increase the concentration of BTA in order to improve the protection effect, the protection film is less removed even when the surface of the copper or copper-based alloy film is scrubbed to lower the CMP rate. In order not to lower the CMP rate, it has been considered necessary to weaken the strength of the protection film and increase the friction effect of the polishing pad. Since the corrosion inhibitor has been restricted substantially to BTA, its strengthen does not change so much even when the composition of the polishing solution differs somewhat. That is, in the conventional abrasive-free polishing solution, it has been considered necessary to form a mechanically weak protection film by using a surfactant and, at the same time, to increase the frictional resistance during CMP. To increase the frictional resistance and increasing the CMP rate, it is effective to add a viscosity increasing agent (refer, for example, to Japanese Patent Laid-open No. 2000-290638: paragraphs [0010] and [0011]).

A polishing method of using an aqueous phosphoric acid solution as an abrasive-incorporated polishing solution in CMP for the copper or copper-base alloy has been known (refer, for example, to Japanese Patent Laid-open No. 7-94455: paragraphs [0012] and [0013]).

There is a polishing method of using a polishing solution comprising polishing abrasive grains, an oxidizer, a complex forming organic acid, a protection film forming agent such as BTA or imidazole and a surfactant (refer, for example, to Japanese Patent Laid-open No. 11-21546 paragraphs [0014] and [0015]). There is an example of using a corrosion inhibitor and a surfactant in combination as a CMP polishing solution (refer, for example, to Domestic Re-publication of PCT International Publication WO00/13217 (pp. 16-18)). In addition, it is also known to enable quantitative evaluation for polishing conditions and friction in CMP by using two-dimensional friction measurement (hereinafter referred to as TDF) capable of measuring friction with high-accuracy during CMP (Meeting Abstracts of the Electrochemical Society, The 18th Meeting, No. 655, Vol. 2000-2, 2000 Phoenix).

### SUMMARY OF THE INVENTION

The specific dielectric constant of FSG used as the low-k film is about 3.5 to 3.7 and the effect of improving the performance is restricted. To further lower the specific dielectric constant, polymeric resin or silicon-containing polymeric resin (hereinafter referred to as silicone) has been considered promising. For example, SiLK (trade name of products manufactured by Dow Chemical Co.) has been generally studied as a material capable of attaining a specific dielectric constant of 2.6 to 2.8 as an example of a hydrocarbon type high polymer resin. Further, HSG2209S-R7 (trade name of products of Hitachi chemical Co., Ltd.) as an example of silicone has a dielectric constant of 2.8. Further, to lower the specific dielectric constant to 2.5 or less, it is considered a porous material in which fine voids are incorporated in the material is effective. However, when the low-k film with a specific dielectric constant of 3 or less is intended to be used for the damascene process, since the mechanical strength of the film is lower compared with a conventional low-k film with a specific dielectric constant of 3 or greater, or adhesion between the low-k film and the metal film or the low-k film and other insulation film is low to result in a problem of often causing delamination upon CMP for the copper or copper-based alloy or the barrier layer. In order to prevent such delamination, a technique of not causing delamination in the step of removing the copper or copper-based alloy in the damascene wiring forming process has been proposed. A method of using electrolytic etching instead of CMP has been proposed (proceedings IEDM 2001, 4.4.1-4.4.4, pp 84-87). However, electrolytic etching suffers from various restrictions such that the copper or copper-based alloy film cannot be removed effectively when an isolated pattern electrically separated from the surroundings is present, or the surface of the copper or copper-based alloy film before etching can not be planarized sufficiently.

Generally, CMP is conducted by an apparatus and procedures shown in the cross sectional view of FIG. 4. A polishing pad 401 made of a polyurethane resin is used for CMP. It has been known that a hard polishing pad is excellent in the planarization effect over the soft pad. The polishing pad 401 is rotated while being appended on a disk referred to as a rotationally driven polishing platen 400. There is also a system of using a polishing pad in a belt-like shape which is moved rotationally by a motor driven roller. Holes or trenches (not illustrated) are provided on the surface of the polishing pad 401. They intend to discharge dusts formed by CMP efficiently thereby suppressing formation of polishing scratches. A substrate 404 to be polished is fixed to a jig referred to as a carrier 403 and pressed to the polishing pad 401 by a predetermined CMP pressure while being rotated by a motor (not illustrated). A porous resin sheet (not illustrated) referred to as a backing pad is often used to secure the substrate 404 to the carrier 403. When a polishing solution (not illustrated) is supplied by way of a supply port 407 onto the polishing pad 401, the surface of the substrate 404 is scraped off by friction, mainly, by abrasive grains in a case where abrasive grains are incorporated at the surface of the polishing pad 401 and in the polishing solution. A circular pad referred to as a retainer 402 is disposed on the periphery of the substrate to be polished 401 such that the polished substrate 404 is not detached from the carrier 403. In a case of applying CMP to plural kinds of thin films, a polishing solution used exclusively for them respectively are often used and, for this purpose, the CMP apparatus also has a plurality of polishing platens and the substrate to be polished is moved to respective polishing platens on every types of the polishing solutions used for conducting CMP. Further, the surface state of the polishing pad gives an intense effect on CMP characteristics. Then, a treatment referred to as dressing or dress is applied in order to keep the surface of the polishing pad to a constant state. Generally, a tool referred to as a dresser 406 in the shape of a disk or doughnut buried with diamond particles 405 is pressed under rotation to the surface of the polishing pad 401 to roughen the surface. For the dressing, there are known a method of conducting dressing simultaneously during CMP for the substrate 401 to be polished (referred to as concurrent dressing) and a method of conducting dress while CMP is not conducted such as before CMP or during exchange of a substrate to be polished (referred to as intermittent dressing).

It is necessary to decrease the friction during CMP to suppress polishing scratches or delamination. It is necessary to lower the CMP pressure to decrease the friction during CMP using a conventional polishing agent.

However, in CMP for metal films, a CMP pressure of about 200 g per square cm (hereinafter referred to as 200 g/cm²) is used. This CMP pressure is a lower limit for the conventional practical pressure range and, when the CMP pressure is decreased to a level lower than the limit, it results in a problem that CMP cost increase remarkably because of the lowering of the CMP rate, or that CMP itself becomes unstable such as degradation of uniformness, and the friction reducing effect is different depending on the type of the polishing solution even when CMP pressure is lowered such that delamination is not formed depending on the type of the polishing solution, or delamination can not be solved unless a further lower CMP pressure is provided. In the case of using the abrasive-free polishing solution, it shows a trend that polishing scratches are less formed and delamination is less caused. However, since no sufficient stability can be obtained, reduction of friction is still necessary. Even when it is intended to decrease friction during CMP, there exists a basic problem that no effective method for quantitatively measuring actual friction in CMP is not present. Accordingly, to confirm whether friction is decreased sufficiently or not in a case of using a predetermined polishing solution, it was studied in a try and error manner such as observation for the occurrence of delamination by actually conducting CMP.

Several attempts have been reported for the measurement of friction during CMP. One of most well known methods is an attempt of measuring friction by measuring the amount of torque or current of a motor for rotating a polishing platen and, for example, 2350 PLANARIZATION CONTROLLER (trade name of products manufactured by LUXTRON Co.) is marketed. However, the value of the torque or current of a motor that rotates a heavy polishing platen of several hundreds kg or more is large and it is difficult to detect a slight change therein caused by the friction of an LSI substrate to be polished. Further, in a case, for example, of conducting concurrent dressing in the apparatus shown in FIG. 4, a load caused by friction by the dresser 406 is also applied. Further, the retainer 402 provided in the convention CMP apparatus is pressed to the polishing pod 401 at a pressure about equal with that pressing the substrate 404 to be polished, in which the torque caused by friction between the retainer 402 and the polishing pad 401 is as large as comparable with friction between the substrate 403 to be polished and the polishing pad 401. As described above, even if a detection method for the motor torque or the current is used, it was practically impossible to detect only the change of the friction caused by CMP for the copper or copper-based alloy. Actually, this can only detect the change of torque at the instance where the change of friction is most violent such as at the instance the underlying insulation layer is exposed upon completion of CMP for the copper or copper-based alloy.

For the oxidizer, the etchant and the protection film forming agent used in the invention, there are the following examples of reports. As an example of the etchant used for the polishing solution, use of an aqueous phosphoric acid solution for the abrasive-incorporated polishing solution for the copper or copper-based alloy is described (refer, for example, to Japanese Patent Laid-open No. 7-94455, paragraphs [0012] and [0013]), in which the polishing rate of the insulation film is suppressed by addition and use of phosphoric acid to the abrasive-incorporated polishing solution to improving the CMP rate relatively for the copper or copper-based alloy. However, while the ratio of the CMP rate is improved, the level of the CMP rate itself is low and not practical, so that the effect of the addition of phosphoric acid is not so remarkable. Further, combination with abrasive grains is indispensable for effectively conductive CMP.

Another CMP polishing solution for the copper or copper-based alloy comprises polishing abrasive grains, oxidizer, complex forming organic acid, protection film forming agent such as BTA or imidazole and a surfactant (refer, for example, to Japanese Patent Laid-open No. 11-21546, paragraphs [0014] and [0015]). It is described that an inorganic acid such as phosphoric acid can be added in order to control the hydrogen ion concentration pH of the polishing solution or for promoting the polishing rate of the barrier metal film. The surfactant described therein is for suppressing settling, agglomeration and dissolution of polishing abrasive grains, and the polishing solution is a polishing solution relying essentially on the mechanical removing effect by the abrasive grains for the copper or copper-based alloy oxides. This prior art is similar in that a protection film forming agent such as BTA is used for improving the CMP accuracy, and the surfactant is added for stabilization but CMP itself solely relies on the mechanical polishing effect of the abrasive grains and it suggests nothing at all about the possibility of using it as a abrasive-free polishing solution.

As has been described above, use of phosphoric acid as the ingredient of the polishing solution has been disclosed in the prior art. However, any of the examples is based on the premise for the scraping effect of the abrasive grains and no suggestion can be obtained about the abrasive-free polishing solution.

Examples for conducting CMP by using a polishing pad incorporated with abrasive grains while not incorporating abrasive grains in the polishing solution itself have been well known. However, in the examples described above, what contributes to the scraping effect of CMP is only the abrasive grains in the polishing pad in which the mechanism for polishing is equivalent with conventional CMP comprising a combination of a polishing solution containing abrasive grains and a polishing pad not incorporated with abrasive grains.

There are the following reports of the corrosion inhibitor. In addition to the document (refer, for example, to Japanese Patent Laid-open No. 11-135466: paragraphs [0008] and [0009]), an example of using a corrosion inhibitor and a surfactant in combination is disclosed (refer, for example, to Domestic Republication of PCT International Publication WO00/13217 (pp. 16-18)) in which BTA is used as the corrosion inhibitor which is in combination with a surfactant. Further, for the effect of the viscosity improving agent (refer, for example, to Domestic Republication of PCT International Publication WO00/13217 (pp. 16-18)), it shows that the polishing rate is further increased by increasing the molecular weight and thus increasing the viscosity of the surfactant. It is estimated that since the molecular weight of the surfactant increase, the friction resistance between the polishing pad and the copper or copper-based alloy is increased. In the examples, the corrosion inhibitor means a material that reacts with the surface of a copper or copper-based alloy film to form a less water soluble layer and serves to inhibit a further proceeding of reaction to the inside of the copper or copper-based alloy film. On the other hand, it is assumed that the surfactant deposits to the film surface to form a film, rather than reacts with the copper or copper-based alloy, thereby retarding the reaction between the polishing solution and the copper or copper-based alloy film or functions to bring the polishing solution into uniform contact with the surface of the copper or copper-based alloy film, but no detailed mechanism is not apparent at present. It is considered that the surfactant has no substantial effect of taking place chemical reaction vigorously with a surface of copper or copper-based alloy film, different from the corrosion inhibitor.

As has been described above CMP for the copper or copper-based alloy by using an abrasive-incorporated polishing solution involves a problem of often causing delamination upon forming wiring of the copper or copper-based alloy by using a low-k film. While the use of the abrasive-free polishing solution provides a slight improvement, the effect was not sufficient. In the conventional abrasive-free polishing solution for keeping the concentration of the corrosion inhibitor as low as possible, only one type of a corrosion inhibitor, which is practically restricted to BTA, is used at a low concentration to the etchant comprising the oxidizer and the organic acid and intended to compatibilize the CMP rate and the planarization effect while increasing the corrosion inhibiting effect and friction by using the surfactant. However, the effect is not sufficient and delamination has often been caused, for example, in CMP for the copper or copper-based alloy, for example, on the low-k film. Further, it also involves a problem that the CMP rate is lower compared with the abrasive-incorporated polishing solution.

The present inventors enable quantitative evaluation for the polishing condition and the friction in CMP by using two dimensional friction measurement (hereinafter referred to as TDF) capable of measuring friction during CMP at high concentration (for example, refer to Meeting Abstracts of the Electrochemical Society, The 18th Meeting, No. 655, vol. 2000-2, 2000, Phoenix). This method can detect the change of friction at a high sensitivity of 10 times or more compared with the existent method, for example, of measuring the motor torque during CMP. FIG. 5 is an upper plan view of a TDF apparatus manufactured by the inventors. At first, a fluoro resin of a low friction with a friction pad 501 is used for a retainer (not illustrated) and the pressure pressing on the friction pad 501 is reduced to 10 g/cm² or less thereby decreasing the frictional force caused by the retainer to a negligible level. Since the pressure applied to the retainer is sufficiently low, the material for the retainer is not necessarily be restricted to the fluoro resin. Further, a substrate to be polished (not illustrated) was directly affixed to a carrier 503 without using the retainer and measurement was conducted and the result was compared with the friction in a case of using the retainer to confirm that the difference between both of them is negligibly small. A disk of 50 cm diameter was used as a polishing platen (not illustrated), on which various types of polishing pads 501 can be affixed. While the polishing platen of this size can measure the substrate to be polished of a diameter up to 8 inches but the diameter of the polishing platen is not restricted thereto. Further, it is not always necessary to append the polishing pad 501 to a circular polishing platen but a type of driving the belt-shape platen by a roller may be used. In the circular polishing platen, a polishing solution (not illustrated) was supplied to the center of the platen in order to keep the measuring condition constant. A modification such as dropping just before the carrier 503 may be adopted in a case of intending to measure the friction while simulating a specific CMP step. The carrier 503 is configured to be movable forward to backward and leftward to rightward, and the force exerted on the carrier 503 was detected by using a load cell 508 for supporting the direction parallel with the tangent direction of movement of the friction pad 501 and a load cell 509 in the direction vertical thereto. The output signal is introduced into a recorder for drawing, or converted into a graph by a computer.

The present invention has been accomplished while quantitatively evaluating the polishing solution or mechanical characteristics of CMP conditions by using TDF measurement and intends to newly provide a polishing solution with a sufficiently low friction during CMP and not substantially containing abrasive grains (abrasive-free polishing solution). Specifically, the invention provides an abrasive-free polishing solution having a low friction characteristics with a dynamic friction coefficient remarkably lower than usual as less than 0.5, preferably, 0.4 or less, further preferably, 0.3 or less and provides a polishing solution and a polishing method capable of suppressing delamination of films while maintaining a polishing rate at 300 nm/min or more also in a process of damascene wiring process for the copper or capper based alloy, comprising copper or copper-based alloy and a low-k insulation film in combination by conducting CMP under the conditions at a friction force of 100 g/cm² or less. The frictional force is preferably 80 g/cm² or less.

Further, addition of abrasive grains to the polishing solution or addition of a complex salt of a copper or copper-based alloy enables a more extended application use and more excellent process.

The foregoing object can be attained by scrubbing the surface of a metal film while supplying a polishing solution, having three or more ingredients comprising, but not a single corrosion inhibitor at least two or more kinds of corrosion inhibitors selected from the group consisting of BTA or derivative thereof, imidazole or derivative thereof, benzimidazole or derivative thereof, naphthotriazole, benzothiazole or derivatives thereof, and a surfactant as a protection film forming agent, one or more of elements selected from the group consisting of organic acids and inorganic acids as an etchant, and containing an oxidizer and water in a metal film polishing method. Further, in a method of reducing friction during CMP, polishing is conducted by using a polishing solution containing a complex salt of a copper or copper-based alloy in addition to the polishing solution described above.

Heretofore, it has been demanded to suppress the concentration of the corrosion inhibitor to the minimum level in the abrasive-free polishing solution so as not to decrease the CMP rate. To control the etching characteristic or the CMP speed characteristic with a slight amount of addition, only one type of the corrosion inhibitor was used. Further, a surfactant was added with an aim of compensating the insufficiency of the corrosion inhibitive effect. According to the conventional method described above, while this was excellent in the protection characteristic, it was difficult to form a protection film of low friction force. Further, the effect of the etchant is increased by using highly reactive inorganic acid or organic acid but it was difficult to suppress the effect of such a strong etchant by the conventional protection film forming agent. On the contrary, the invention enables to form a corrosion inhibitive protection film of low frictional coefficient with less undesired effects on the polishing characteristics while attaining a sufficient effect of suppressing the strong etchant by combining a plurality types of corrosion inhibitors.

In the present invention, the following relation is further disclosed for the role of the etchant and the corrosion inhibitor. In a case of using the etchant having a strong effect, it is necessary that the corrosion inhibitor also has a strong effect. An example of a strong etchant includes a combination of an inorganic phosphoric acid and an organic lactic acid. While the corrosion inhibitor having a strong effect BTA can be mentioned but, when the concentration is increased excessively, it increases friction and remarkably decreases the polishing rate. It has been found that addition of imidazole is effective without increasing the concentration of BTA by so much in order not to increase the friction and not to decrease the polishing rate by so much.

On the other hand, in a case where it is not necessary to increase the polishing rate by so much, another combination is effective. That is, in a case of using a plurality types of organic acids as an etchant, since the etching effect is not so strong, it is not necessary to increase the effect of the corrosion inhibitor by so much as well. A combination of a plurality of organic acids can include, for example, a combination of malic acid and lactic acid. In this case, a corrosion inhibitor comprising BTA only or BTA with addition of a slight amount of imidazole can be used. A slight amount of imidazole means a case where the concentration is 0.05% or less and 0.0001% or more. Similar characteristics can be developed without incorporating imidazole. However, addition of imidazole is effective for the stabilization of the polishing rate and the improvement in the uniformness of polishing.

The reason why excellent corrosion inhibiting effect can be obtained irrespective of low friction by the combination of a plurality of corrosion inhibitors compared with the conventional case of using a single type of corrosion inhibitor is estimated as described below. Since the corrosion inhibitors have different nature regarding the corrosion inhibitive effect of copper or copper-based alloy, excellent corrosion inhibitor characteristic can be developed by the combined use of a plurality of them. For example, BTA or the derivatives thereof are most excellent in view of the level of the corrosion inhibiting effect but the rate of reacting with the surface of copper or copper-based alloy to form a protection layer is somewhat slow. While the formed protection film is excellent in the corrosion inhibiting effect, it remarkably lowers the polishing rate. On the contrary, it is supposed that imidazole and derivatives thereof have a high rate to react with the surface of the copper or copper-based alloy to form a protection layer but neither the corrosion inhibiting effect nor the mechanical strength of the protection layer is not so great. It is likely that when BTA and imidazole are used in combination, a mechanically weak protection layer is formed at first by imidazole, on which a protection layer of BTA is formed. Since the mechanical property is determined by the protection layer with imidazole, it is considered that a protection film which is easily polished and excellent in the corrosion inhibitor effect is formed. While a surfactant is also added to the polishing solution, the concentration is remarkably lower than usual. Further, probably, the role thereof is different from the conventional protection film forming effect but provides an effect of stabilizing the friction characteristics on the surface of the protection film. Actually, it has been found that the change of the etching rate is small, that is, contribution of the polishing solution to the etching property is small even when the concentration of the surfactant is changed.

Phosphoric acid is particularly effective as the etchant and this has an effect of rendering oxides on the surface of the metal film water soluble. For phosphoric acid, ortho-phosphoric acid is typical and, unless otherwise specified, ortho-phosphoric acid is described as phosphoric acid in the present invention. In addition, phosphorous acid, hypo-phosphorus acid, meta-phosphoric acid, poly-phosphoric acid such as diphosphoric acid can be used. Ortho-phosphoric acid is excellent in the chemical stability and is most advantageous in view of the cost since it is inexpensive. Phosphorous acid or hypophosphorus acid has a merit of lower toxicity compared with orthophosphoric acid. Further, phosphorus acid has a merit of causing less roughness on the polished surface compared with orthophosphoric acid.

An organic acid is also effective as the etchant and it has been found that combined use of an organic acid and an inorganic acid or plural organic acids is further effective than sole use. Among the organic acids, carboxylic acid and hydroxycarboxylic acid containing hydroxyl group or carboxyl groups have a higher effect of increasing the polishing rate. Such organic acid can include, for example, those organic acids such as citric acid, malic acid, malonic acid, succinic acid, tartaric acid, phthalic acid, maleic acid, fumaric acid, lactic acid (α-hydroxy-propionic acid or β-hydroxy-propionic acid), pimelic acid, adipic acid, glutaric acid, oxalic acid, salicylic acid, glycolic acid, tricarbamic acid, benzoic acid, formic acid acetic acid, propionic acid, butyric acid, valeic acid, and acrylic acid, as well as salts thereof. Further, the chemicals may be used in combination of a plurality of them. Further, in the polishing solution using the acid described above, hydrogen ion concentration of the solution (hereinafter referred to as pH) sometimes changes excessively to an acidic region giving undesired effects on the life, the etching property, characteristic and the polishing characteristic of the polishing solution. In order to prevent such undesired effects, pH may be controlled by adding an aqueous alkaline solution, for example, aqueous ammonia, or an aqueous solution of an organic amine in combination with the acid. When the alkaline solution is added, the organic acid described above is partially or entirely reacted with the alkaline agent to form a salt. pH control is conducted while considering the change of the polishing characteristic and the etching characteristic by the change of the acid into the salt. pH of the polishing solution for the copper or copper-based alloy is particularly preferably within a range from 4.0 to 7.0.

Among the acid described above, malonic acid, malic acid, citric acid, succinic acid, maleic acid, fumaric acid, α-hydroxypropionic acid or β-hydroxypropionic acid (usually α-hydroxypropionic acid being used and hereinafter referred to as lactic acid) is preferred as the organic solvent to be added to the polishing solution according to the invention with the view point of high polishing rate and low etching rate.

In particular, the lactic acid is generally used also as food additives and it is not only advantageous in view of low toxicity, non-smelling and high solubility but is also excellent in the effect of improving the polishing rate in a case used in combination with other acid.

Among the protection film forming agent, the corrosion inhibitor to the copper or copper-based alloy usable herein can include, for example, BTA, imadazole, benzimidazole, naphtotriazole, benzotriazole and derivatives thereof.

For BTA derivatives, 4-methyl-1.H-benzotriazole, 4-carboxyl-1.H-benzotriazole, and 5-methyl-1.H-benzotriazole can be used, for example.

As the imidazole derivative, 4-methylimidazole, 4-methyl-5.hydroxymethylimidazole, and 1-phenyl-4-methylimidazole can be used, for example.

As the benzoimilazole derivative, 2-mercaptobenzimidazole, 2-(n-methylpropyl)-benzimidazole (n=1, 2), 2-(n-methylbutyl)benzimidazole (n=1, 2, 3), 2-(1-ethylpropyl)-benzimidazole, and 2-(1-ethylpropyl)-methylbenzimidazole can be used, for example.

As the benzothiazole derivative, 2-mercaptobenzo thiazole and 2,1,3-benzothiazole can be used, for example.

However, most of derivatives described above are less water soluble and often require any chemical for rendering them water soluble as a solubilizing agent. For example, in the case of the imidazole derivative, use of lactic acid as the solubilizing agent is necessary for attaining the practical concentration. However, when lactic acid is used it requires a care since the etching rate is also changed. Also in a case of BTA derivative, alcohol or organic alkali, etc. is used as a solubilizing agent.

Further, in a case of using the derivative, while it can provide a merit capable of developing an extremely strong corrosion inhibiting effect, it has been found that the distribution of the polishing rate with the plane tends to be increased when a substrate of a large area is polished in a case of using a less water soluble material. It is likely that ingredients are separated from each other in the narrow gap between the substrate and the polishing pad during polishing because of the less soluble material to greatly change the composition of the polishing solution between the outer circumference and the central portion of the substrate. This results in a significant problem for polishing the wafer with a diameter of 8 inch or more. In the invention, a most preferred polishing solution can be obtained by the combined use of BTA and imidazole. Since an aqueous solution of a required concentration can be obtained easily for both of them without solubilizing agent, preferred uniformness can be obtained for CMP. The preferred concentration is within a range of 0.05 to 2.0% by weight for BTA within a range from 0.05 to 3.0% by weight for imidazole. They are concentration ranges suitable to keep the etching rate to 3 nm/min or less while keeping the CMP rate in a practical range. In particular, the range from 0.05 to 1.0% by weight for BTA and a range from 0.05 to 1.5% by weight for imidazole are suitable.

While imidazole has been known, like BTA, as a corrosion inhibitor for copper or copper-based alloy, the corrosion inhibiting effect as a single element is not sufficient to copper or copper-based alloy and it has been found that the effect of suppressing the etching rate can be attained only by the combined use with BTA. While BTA is excellent in the corrosion inhibiting characteristic, when the necessary etching characteristic is intended to be attained only by BTA, since this also decreases the polishing rate remarkably, the corrosion inhibiting effect was compensated by a surfactant such as a polyacrylic acid while lowering the concentration of BTA. However, since a great amount of polyacrylic acid was added, it involved a problem of greatly increasing the frictional resistance during CMP. On the contrary, combined use of BTA and imidazole can attain a sufficient etching suppression effect while keeping the frictional resistance low. In addition, it also has an effect of not decreasing the polishing rate by so much. Since the polishing solution using both of them in combination, particularly, a polishing solution containing a great amount of imidazole is extremely less frictional and sometimes cause slipping on the surface to be polished depending on the polishing conditions, it is effective to control the frictional characteristic or wettability of the polishing solution with addition of a slight amount of a surfactant.

As regards polishing abrasive grains, when alumina abrasive grains or silica abrasive grains are incorporated in the polishing solution of the invention, an effect of further increasing the polishing rate of the can be expected. When abrasive grains are incorporated in the polishing solution, the barrier layer and the insulation film are also polished even when for the Cu polishing solution and the so-called polishing selectivity is lowered. The average grain size of the abrasive grains is suitably 0.1 μm or less and, preferably, 20 nm or less. When polishing is conducted excessively, the barrier layer and the insulation layer are also polished to sometimes lower the fabrication accuracy of copper wiring. The degree of lowering the selectivity changes also depending on the concentration of abrasive grains added. In order not to cause excess lowering, the concentration of the abrasive grains is 5% by weight or less, preferably, 1% by weight or less and, further preferably, 0.1% by weight or less. Addition of abrasive grains at a concentration of 1% by weight is effective for the prevention of the occurrence of copper polishing residue. That is, a number of minute unevenness are present on the surface of the insulation film underlying the copper layer or the barrier layer and when copper polishing at extremely high selectivity is conducted, copper polishing residue tends to be formed at the skirt portions of minute protrusions. However, when the abrasive grains are added, since the minute protrusions are also polished, polishing residues are not formed. In a case where the height of the minute protrusion is as high as 50 nm, the concentration of abrasive grains is preferably from 0.1 to 1% by weight. On the other hand, when the height of the minute protrusions is 20 nm or less, the concentration of the abrasive grains may be 0.1% by weight or less.

Further, in the case of combined use of BTA and imidazole as in the invention, imidazole shows not only the corrosion inhibiting effect but also develops an effect of remarkably decreasing the frictional force during polishing. When the concentration of imidazole is high, frictional force during polishing may sometimes be lowered excessively to lower the polishing rate. In this case, it is effective to add the abrasive grains in order to keep the polishing frictional force at an appropriate value. In this case, the abrasive concentration is suitably within a range from 0.005 to 0.1% by weight. However, to suppress the lowering of the fabrication accuracy of copper wiring due to the lowering of the selectivity, the excess polishing is preferably suppressed by about 30% increase relative to the film thickness in the planer portion.

Further, a polishing pad incorporated with abrasive grains (hereinafter referred to as pad with abrasive grains) may be used. For example, those in which the abrasive grains are incorporated in the resin bonded material (hereinafter referred to as polymer particle of island state) and the bonded material are further dispersed in the resin of higher hardness (hereinafter referred to as polymer particle of sea state) are particularly preferred. The ratio of the abrasive grains incorporated in the polymer particle of island-state is preferably within a range from 0.1 to 5 times (by weight ratio). The diameter of the polymer particles of island-shaped is preferably within a range from 0.1 to 50 μm in the major diameter. As the resin constituting polymer particle of island state, rubber, polyurethane, polyester, nylon type elastomer, epoxy resin, urea resin and urethane type resin can be used. As the polymer particle of sea-state, those resins having a Rockwell hardness M55 to 125 and harder than the polymer particle of island-state are suitable. In particular, rigid polyurethane resin is excellent in view of the wear resistance. In addition, resins such as phenol, polyester and polyamide are suitable. The difference of the hardness between both of them is preferably 5 or more in view of the Rockwell hardness.

However, since a great amount of reaction products are formed during CMP for copper, the pad with abrasive grains is preferably subjected to dressing occasionally. It is preferred to conduct dressing for about one min or more in the course of exchanging substrates after completion of polishing for one sheet of substrate. More preferably, dressing is conducted also during polishing to remove reaction products or diffuse a newly supplied polishing solution for the surface of the pad with abrasive grains. Dressing tools having diamond grains buried to the surface of a metal are preferred and the dressing pressure per unit area obtained by dividing the force applied for dressing by the area of a region in which the diamond grains are buried is preferably within a range from 20 to 350 g/cm². For suppressing the wear of the pad with abrasive grains, a dressing pressure in a range from 20 to 200 g/cm² is particularly preferred. In a case of using the polishing solution of the invention, a dressing pressure from 20 to 100 g/cm² is particularly suitable. The size of the diamond grains used for the dressing tool is preferably within a range from mesh #100 to #300.

In a case of using the polishing solution of the invention with addition of the abrasive grains and in a case of using the abrasive-incorporated pad together, the invention is applicable not only to the polishing for copper but also to the polishing of the barrier layer. In a case of use for the polishing of the barrier layer, it is preferred to further increase the concentration of BTA or imidazole in the polishing solution. When the concentration is increased by 0.05% by weight or more compared with the case of use for the polishing of copper, an effect of suppressing the rate of polishing copper can be obtained. This can suppress excessive polishing of the copper layer during polishing of the barrier layer, which is advantageous for the improvement of the fabrication accuracy of copper wiring. In the polishing described above, a polishing pressure within a range from 50 to 200 g/cm² and a sliding speed of from 60 to 120 m/min are particularly suitable to the polishing of copper and the barrier layer on the low-k material. Occurrence of polishing scratches and delamination can be suppressed by combining the polishing solution of the invention with the range of the polishing condition described above.

It is to be described that the invention can provide a CMP step capable of suppressing delamination by adding a complex salt of a copper or copper-based alloy. The complex salt of the copper or copper-based alloy is preferably a reaction product of the same acid as the organic or inorganic acid contained in the polishing solution and the copper or copper-based alloy with no particular restriction to them. For example, when a solution mixture of phosphoric acid and lactic acid, optionally, containing a surfactant and the copper or copper-based alloy are reacted, a green liquid containing the complex salt of copper or copper-based alloy is obtained. A surfactant may be added to the liquid to form a liquid with increased viscosity. Further, the complex salt may be previously supplied not in the polishing solution but on the polishing pad, to which a predetermined polishing solution may be supplied.

In a case of forming wiring of a copper or copper-based alloy by the damascene method, a CMP process with less dishing or erosion can be attained by conducting CMP at several steps under the conditions scarcely applying CMP for the barrier film or the insulation film in CMP for the copper or copper-based alloy and under the condition at which the CMP rate for the barrier film is most increased in CMP for the barrier layer. In a case where the barrier layer is made of Ti or TiN, use of abrasive free polishing solution is convenient. For example, an abrasive-free polishing solution comprising hydrogen peroxide and an aromatic nitro compound can be used. The aromatic nitro compound functions as an oxidizer for promoting the etching of the titanium compound. The protection film forming agent can be added optionally. While the polishing rate is slow compared with the polishing solution with addition of abrasive grains, it is possible to make the process for forming wiring of the copper or copper-based alloy into a completely abrasive-free process.

The aromatic nitro compound described above can include, for example, nitrobenzene sulfonic acid, nitrophenol sulfonic acid, 1-nitronaphthalene-2-sulfonic acid, sulfonates thereof, nitrobenzoic acid, 4-chloro-3-nitro benzoic acid, nitrophthalic acid, isonitrophthalic acid, nitroterephthalic acid, 3-nitrosalicylic acid, 3,5-dinitrosalicylic acid, picric acid, aminonitro benzoic acid, nitro-1-naphthoic acid, and calboxylates thereof. The salts described above can include sodium salt, potassium salt and ammonium salts, the ammonium salts being most preferred as chemicals used for the semiconductor devices. Potassium salts are preferred next to them since the diffusion coefficient in the semiconductor device is small. They can be used alone or as a combination of two or more of them. In the case of tungsten nitride (WN) and W, they can be removed by an abrasive-free polishing solution formed by adding 0.5% by weight of BTA to the conventional abrasion-free polishing solution into a state of not causing CMP to copper or copper-based alloy. Dry etching may be conducted in a stage where residue of the copper or copper-based alloy no more gives problem. As an etching gas, a fluorine-containing gas is suitable. While sulfur hexafluoride SF₆ is most suitable, fluoro carbon gas or a fluorinated hydrocarbon gas may also be used.

### BRIEF DESCRIPTION OF THE DRAWINGS

FIG. 1 is a graph showing the dependence of frictional force on the flow rate of a polishing solution in comparison with a conventional case;

FIG. 2 is a graph showing the dependence of the CMP rate on a CMP pressure in comparison with a conventional case;

FIG. 3 is a graph for comparing the dependence of the frictional force on the CMP time in a case of using a polishing solution of the invention between a case of using a polishing solution not containing a complex salt of copper or copper-based alloy and a case of using a polishing solution with addition of a complex salt of copper or copper-based alloy;

FIG. 4 is a cross sectional view showing the concept of a CMP apparatus;

FIG. 5 is an upper plan view showing the concept of a two-dimensional friction measuring apparatus;

FIG. 6A is a cross sectional view of a specimen before conducting CMP by using a polishing solution of the invention;

FIG. 6B is a view showing that CMP for copper or copper-based alloy has been completed but copper or copper-based alloy remains in depressions;

FIG. 6C is a view showing a stage where copper or copper-based alloy and a barrier layer are subjected to CMP till the copper or copper-based alloy in the depressions is removed;

FIG. 6D is a view showing a state where a barrier layer in the depressions is also removed to complete inlaid wiring of a copper or copper-based alloy;

FIG. 7A is a view showing a state of forming up to a device and a tungsten plug on an Si wafer surface;

FIG. 7B is a view showing a state of conducting up to trench fabrication in an insulation film to form the first wiring of copper or copper-based alloy and form a film of copper or copper-based alloy;

FIG. 7C is a view showing a state of forming first wiring of copper or copper-based alloy and forming a protection film of a copper or copper-based alloy layer;

FIG. 7D is a view providing holes and trenches for second wiring layer and forming an alloy layer over the entire surface;

FIG. 7E is a view forming a second copper or copper-based alloy layer in holes and trenches for the second wiring layer;

FIG. 7F is a view for planarizing the second copper or copper-based alloy layer by a polishing method of the invention;

FIG. 8 is a plan view illustrating a portion of the cross section in FIG. 7F;

FIG. 9 is a graph showing the dependence of the polishing rate for a copper or copper-based alloy film on the concentration of malic acid/lactic acid;

FIG. 10 is a graph showing the dependence of the polishing rate with respect to a copper or copper-based alloy film on BTA/imidazole concentration;

FIG. 11 is a graph showing the dependence of the dishing depth after conducting CMP to a copper or copper-based alloy film on the concentration of malic acid/lactic acid;

FIG. 12 is a graph showing the dependence of the polishing rate to a copper or copper-based alloy film on the concentration of hydrogen peroxide; and

FIG. 13 is a graph showing the-dependence of the dishing depth after conducting CMP to a copper or copper-based alloy on the concentration of hydrogen peroxide.

### DESCRIPTION OF THE PREFERRED EMBODIMENTS

The present invention is to be described specifically with reference to the drawings below.

### EXAMPLE 1

A description will be made of the difference of characteristics between the abrasive-free polishing solution of the invention and a conventional abrasive-free polishing solution mainly on the frictional characteristics. A solution comprising 0.15% by volume of phosphoric acid as a first etchant, 0.6% by volume of lactic acid as a second etchant, 0.2% by weight of BTA as a first corrosion inhibitor, 0.4% by weight of imidazole as a second corrosion inhibitor, 0.05% by volume of polyacrylic acid neutralized with ammonia as a surfactant, 30% by volume of hydrogen peroxide (H₂O₂ concentration: 30 wt %) and the balance of deionized water was used as the abrasive-free polishing solution of the invention. In this case, solid materials are represented by % by weight while liquid materials were represented by % by volume. As a substrate to be polished, a 4-inch silicon wafer having a thermally oxidized SiO₂ film formed on the surface was used, on which an alloy film comprising Ta of 20 nm in thickness, copper or copper-based alloy film of 2 μm in thickness was formed. The copper or copper-based alloy film was a stacked film of a sputtered film of 100 nm in thickness and a plated copper or copper-based alloy film of 1.9 μm in thickness. While using them, a CMP rate was evaluated while measuring the frictional force by using the TDF measuring apparatus described above. The CMP rate was determined by conversion from the change of the sheet resistance of the copper or copper-based alloy film before and after CMP.

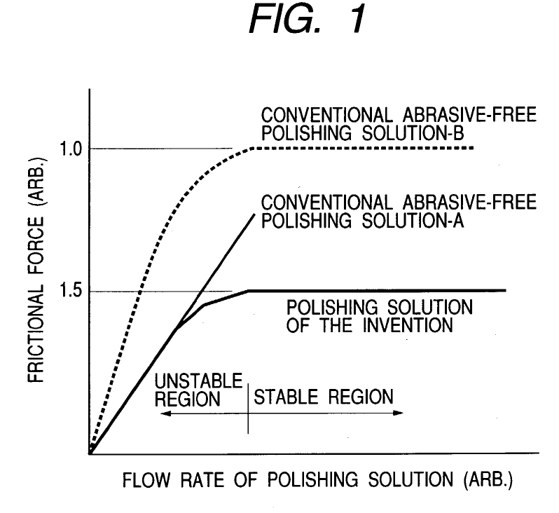

Using the fresh abrasive-free polishing solution described above, CMP was conducted for a predetermined time while measuring the frictional force by using the TDF apparatus to determine the CMP rate. IC1000 (trade name of products of Rodel Co,) made of foamed polyurethane resin was used as a polishing pad, the CMP pressure of 200 g/cm² and the relative speed between the substrate to be polished and the polishing pad (referred to as sliding speed) was 60 m/min. FIG. 1 shows the dependence of the frictional force on the polishing solution in comparison. In the graph, frictional characteristics of the conventional abrasion-free polishing solution-A correspond to HS-400 (trade name of products manufactured by Hitachi Chemical Co., Ltd.) that is a polishing solution using BTA and a surfactant as the protection film forming agent but not containing ingredients of high viscosity. The conventional abrasive-free polishing solution-B corresponds has substantially the same as chemical ingredients but is incorporated with a viscosity improving agent to increase the frictional force and HS-C430 (trade name of products manufactured by Hitachi Chemical Co., Ltd.) corresponds thereto. Referring to the conventional abrasion-free polishing solution-B, in a region with less polishing solution flow rate (unstable region), the frictional force increased along with the polishing solution flow rate and then settled to a predetermined value of 120 g/cm². That is, the coefficient of the dynamic friction was 0.6 and the CMP rate in this case was about 400 nm/min. While the conventional abrasive-free polishing solution-A showed lower frictional force at the same CMP pressure, the CMP rate was also lowered greatly and it was estimated that the frictional force had to be increased remarkably in order to obtain a comparable CMP rate.

On the contrary, in the abrasive-free polishing solution of the invention, the frictional force in a stable region under the same CMP condition was 55 to 60 g/cm² which was ½ or less compared with the case of the conventional abrasive-free polishing solution. The coefficient of dynamic friction was 0.3 or less. The CMP rate in this case was 460 nm/min which is equal with or more than the usual HS-C430. This means that the CMP efficiency per unit frictional energy was improved by twice or more than usual. The coefficient of the dynamic friction also, for example, by the sliding speed and, a value of about 0.4 or less was attained.

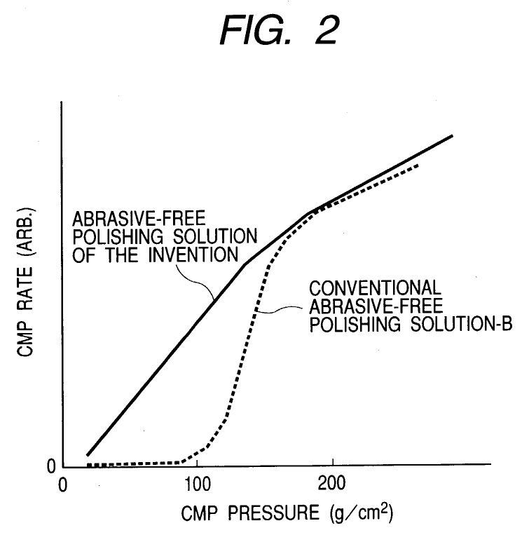

FIG. 2 compares the dependence of the CMP rate on the CMP pressure between the conventional abrasive-free polishing solution-B and the abrasive polishing solution of the invention. In the case of the conventional abrasion-free pressing solution-B, copper or copper-based alloy scarcely undergoes CMP unless a CMP pressure higher than 100 g/cm² is applied. Accordingly, the CMP pressure was necessary by 100 g/cm² or more at the lowest, and the CMP pressure of 200 g/cm² or more was necessary in order to obtain a practical CMP rate, that is, 400 nm/min or more. For CMP of copper or copper-based alloy on the low-k material with a specific dielectric constant of 3 or less, it is at first required that the CMP pressure is lowered to about 100 g/cm². However, in the conventional abrasive-free polishing solution-B, it is actually difficult to lower the CMP pressure since CMP is scarcely conducted. Then, when CMP is conducted without lowering the CMP pressure, stress concentration due to the deformation of the pressing pad or the like is caused on the periphery of the substrate to be polished even if the frictional force is decreased by some or other means, tending to readily cause delamination. That is, in the CMP for the substrate to be polished from which copper or copper-based alloy is tended to be delaminated, it is necessary to not only reduce the frictional force but also lower the CMP pressure itself. For example, instead of the silicon wafer formed with a thermally oxidized SiO₂ film of the example, a wafer formed at the surface thereto with an SiLK at a specific dielectric constant of 2.7 to 800 nm in thickness and applied with trench fabrication for wiring was used. Then, Ta of 20 nm in thickness and a copper or copper-based alloy film of 2 μm in thickness were formed on the wafer and CMP was conducted. Conditions such as CMP pressure were the same. As a result, copper or copper-based alloy film or a Ta barrier film therebelow on an SiLK film at the wafer periphery was defoliated just after the starting CMP at a rate of about one out of five sheets.

With the abrasive-free polishing solution of the invention, since CMP is started already at a slight polishing pressure, CMP for copper or copper-based alloy is possible, if necessary, at a low pressure of about 50 to 100 g/cm² and it is extremely suitable to CMP for copper or copper-based alloy in a case of using a low-k film as an insulation film. That is, a remarkable feature that not only the frictional force is small at the same CMP pressure and CMP rate but also application of a further lower CMP pressure is possible. When CMP was conducted under the same condition by using the polishing solution of the invention, delamination was scarcely formed. The effect for the delamination on the wafer periphery became more conspicuous as the wafer diameter increased. When the same experiment was conducted by using a wafer of 8-inch diameter, the probability of delamination was increased to about one out of two sheets by the conventional abrasive-free polishing solution-B. However, in the case of using the abrasive-free polishing solution of the invention, the probability of delamination was still small and it remained at 1 out of 10 sheets or less. Further, when CMP was conducted by a process of lowering the CMP pressure to 100 g/cm² just after starting CMP and conducting CMP while increasing the CMP pressure to 200 g/cm² after the lapse of 20 sec after starting CMP, the probability for the delamination of copper or copper-based alloy was further decreased and observed scarcely.

### COMPARATIVE EXAMPLE 1

For a polishing solution formed by removing imidazole from the polishing solution of the invention and controlled such that the etching rate for copper or copper-based alloy film was reduced to a predetermined rate of 3 nm/min or less using only BTA (polishing solution composition: water, phosphoric acid, lactic acid, BTA, methanol, ammonium polyacrylate, aqueous hydrogen peroxide), the average value of the polishing rate within the wafer was 460 nm/min which was substantially the same as that of the polishing solution incorporated with imidazole. However, the distribution of the polishing within the plane was increased to 40% or more and it was no more suitable to CMP with high accuracy.

### COMPARATIVE EXAMPLE 2

A polishing solution was prepared by removing BTA and increasing the amount of imidazole from and in the polishing solution of the invention so that the etching rate for a copper or copper-based alloy film was reduced to a predetermined 3 nm/min or less (polishing solution composition: water, phosphoric acid, lactic acid, imidazole, ammonium polyacrylate and aqueous hydrogen peroxide). Since the imidazole was weak in the corrosion inhibiting effect, it was necessary to lower the concentration of the etchant. In this polishing solution, only 20 nm/min or less of the polishing rate was obtained caused by the lowering of the concentration of the etchant in order to keep the etching rate to an aimed value or less.

### EXAMPLE 2

In this example, a description will be made of a case of conducting CMP for a copper or copper-based alloy film on a substrate to be polished of a large area by using the abrasive-free polishing solution as that in Example 1. A silicon wafer of 8-inch diameter was used as a substrate to be polished. An SiO₂ film of 50 nm in thickness was formed on the surface by a thermal oxidation method, on which a tantalum film and a copper or copper-based alloy film were formed by a known sputtering method each into 50 nm and 1 μm in thickness. Then, CMP for the copper or copper-based alloy was conducted under the same conditions as those in Example 1. However, the flow rate of the polishing solution was set to 300 ml/min. A CMP rate of about 460 nm/min comparable with that for a small substrate of 4-inch diameter was obtained. It is to be noted particularly in this example that the distribution of the CMP rate within the plane at an extremely small value of ±5% or less was obtained irrespective of the use of the large area wafer of 8-inch diameter.

### COMPARATIVE EXAMPLE 2

An abrasion-free polishing solution having a composition substantially the same as that in Example 1 was prepared except use of only 4-carboxyl-1.H-benzotriazole as one kind of BTA derivatives as the corrosion inhibitor and a surfactant as the protection film forming agent. While setting the concentration for phosphoric acid, lactic acid and hydrogen peroxide constant, the BTA derivative and the surfactant were added till the etching rate was reduced to 3 nm/min or less comparable with that in the abrasive-free polishing solution of the invention. Since the BTA derivative is less water soluble, a solubilizing agent was also added. When CMP was conducted under the same conditions as those in Example 2, while the range of about 2 inches from the periphery of the wafer was subjected to substantially uniform CMP, but CMP was scarcely proceeded for the copper or copper-based alloy in the range inside thereof. That is, the distribution of the CMP rate reached as far as ±100% or more relative to the average value. It is supposed that, because of the less solubility of BTA as the corrosion inhibitor, the composition was changed in the course of movement of the polishing solution from the periphery to the center of the wafer to lower the concentration of the etchant and the oxidizer at the central portion of the wafer or, on the other hand, the corrosion inhibitor was accumulated on the central portion of the polishing pad on which the wafer central portion passed.

### EXAMPLE 3

This example shows a case of using a solution formed by further adding a complex salt of a copper or copper-based alloy to the polishing solution of the invention. This is the same as Example 1 except the polishing solution. It has been shown in the example described above that the frictional force can be reduced to ½ of that of the conventional abrasive-free solution by using the abrasive-free solution of the invention. However, the absolute value for the frictional force could not always be kept at 60 g/cm² or less throughout the CMP step.

At first, in FIG. 1 used for the description of Example 1, the reason why the frictional force was low in a case where the flow rate of the polishing solution is low is to be explained as below. A great amount of reaction products are formed during CMP for the copper or copper-based alloy. The reaction product is a complex salt formed by reaction between the copper or copper-based alloy and the etchant. The complex salt serves to function as the so-called lubricant to lower the friction between the surface of the copper or copper-based alloy and the polishing pad. In a case where the flow rate of the polishing solution is small, since the ratio of the reaction product on the surface of the polishing pad to the polishing solution supplied newly, the frictional force is low. The ratio is decreased and the frictional force is increased also along with increase in the flow rate of the polishing solution. When the ratio is reduced to some extant or more, the frictional force no more increases but is stabilized. That is, the frictional force exerting on the copper or copper-based alloy film is smaller in the case of contact with coexistence of the reaction products than in the case where it is in contact only with the new abrasive-free polishing solution.

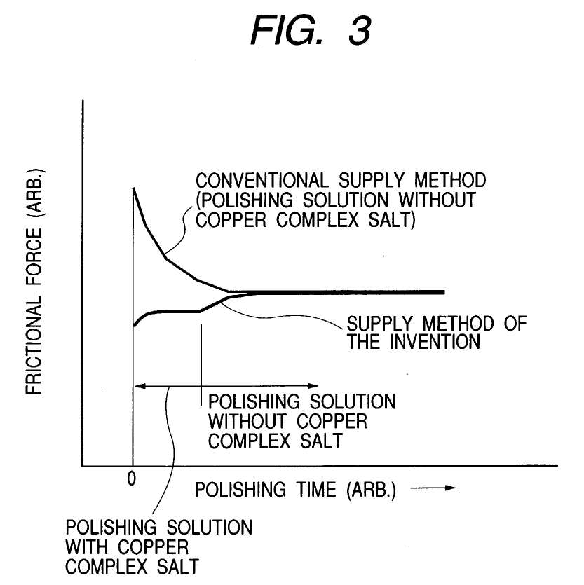

The invention utilizes the phenomenon described above and an example is shown in FIG. 3. The conventional abrasive-free polishing solution supply method in the figure shows the change of frictional force with time when measured under the conditions shown in FIG. 1. When CMP is started while pouring the polishing solution of the invention in a state without a complex salt of the copper or copper-based alloy, the frictional force shows a larger value by about 10 to 30% at the instance of starting relative to the value in a stable state and then rapidly decreases to the frictional value in the stable state. While the phenomenon can be seen both in the case of the conventional abrasive-incorporated polishing solution and in the case of the conventional abrasive-free polishing solution, it is not apparent whether the mechanisms are the same or not. One of the technical problems of the CMP for the copper or copper-based alloy is that the substrate to be polished tends to detach from a carrier just after starting CMP. It is considered that the detaching phenomenon is attributable to a large frictional force at the instance just after starting CMP. In particular, in a case of the abrasive-free CMP, it is likely that the surface of the copper or copper-based alloy is exposed only to a fresh polishing solution just after starting CMP for the copper or copper-based alloy and, accordingly, the frictional value is somewhat large and, subsequently, a reaction product is formed to provide a composition in a state mixed with a fresh abrasive-free CMP solution to reach a stable state. Accordingly, since a large frictional value is exhibited just after starting CMP, there is the possibility that delamination occurs at the instance of starting CMP. Then, a complex salt of the copper or copper-based alloy is further added to the abrasive-free polishing solution of the invention. Supply of a polishing solution with a complex salt of the copper or copper-based at first can prevent occurrence of large frictional force just after starting CMP. Since the CMP state is stabilized when the number of rotation of the polishing platen reaches about several to 20 rotations, delamination can be suppressed further safely while scarcely deteriorating the CMP processing performance by changing the solution to an abrasive-free polishing solution without complex salt. The addition amount is suitably from 0.05% by weight or more and 50% by weight or less. Several to 20 rotations are required for the surface of the polishing platen to reach a stable state. It may be controlled in accordance with the flow rate of the polishing solution, dressing state or the mechanical strength or the adhesion property of the low-k film used.

In the example, a polishing solution had a composition formed with addition of 5% by weight of a complex salt obtained by reacting copper or copper-based alloy with phosphoric acid and lactic acid to the polishing solution shown in Example 1 and decreasing water by so much. When CMP for a copper or copper-based alloy was conducted by supplying this polishing solution at 130 ml/min, frictional force was 40 g/cm² and the coefficient of the dynamic friction was 0.2. Supply of the solution with the complex salt of the copper or copper-based alloy was terminated at a stage where the polishing platen rotated by 10 turns from the start of CMP, and the CMP was continued while switching to the abrasion-free polishing solution of Example 1 not containing the complex salt of the copper or copper-based alloy. Since the CMP rate by the polishing solution with addition of the complex salt of the copper or copper-based alloy was reduced to 300 nm/min which was lowered by about 20% compared with the case of not adding the same, the lowering of the throughput of CMP could be suppressed to a minimum limit by returning to the polishing solution with no addition of the complex salt. As a more simple and convenient method, when an aqueous solution containing 10% by weight of a copper complex salt was previously supplied onto a polishing pad for one min at 100 ml/min and then CMP was conducted while supplying the same polishing solution as that in Example 1, comparable result was obtained.

Then, an SiLK film with specific dielectric constant of 2.7 was formed on an Si wafer, on which tantalum and a copper or copper-based alloy were formed by a known sputtering method to 50 nm and 1.5 μm in thickness respectively and CMP was conducted. Since a large step was formed on the wafer periphery in a case of using the abrasive-free polishing solution of the invention without complex salt, delamination was observed, although seldom, near the step. However, when the polishing solution of the invention with the complex salt was used at first and then switched to a solution without the complex salt after 10 sec, delamination did not occur at all and stable CMP could be attained. In particular, this is suitable to CMP for a copper or copper-based alloy in combination with the low-k material.

### EXAMPLE 4

In this example, a method of attaining a high polishing rate comparable with the abrasive-incorporated polishing solution is to be explained. A substrate to be polished used for the measurement of CMP rate is the same as that in Example 1. The abrasive-free polishing solution of the invention used had a composition comprising 0.7% by volume of phosphoric acid as a first etchant, 1.2% by volume of lactic acid as a second etchant, 0.4% by weight of BTA as a first corrosion inhibitor, 0.15% by weight of polyacrylic acid neutralized with ammonia as a surfactant, 30% by volume of aqueous hydrogen peroxide and the balance of deionized water. Imidazole was added as a second corrosion inhibitor so as to suppress the etching rate to 3 nm/min or less. When a CMP experiment was conducted under the same conditions as those in Example 1, 850 nm/min of the CMP rate was obtained. Since the polishing solution of this example aims at higher CMP rate and is not intended for lowering of the frictional force, TDF measurement was not conducted. However, it was confirmed that the frictional force was lower than that of the conventional abrasive-free polishing solution under the same CMP conditions. Further, the distribution of the CMP rate within the plane of the substrate was also satisfactory as 7%.

### EXAMPLE 5

In this example, description is to be made to a case of using an acid other than phosphoric acid as the first etchant in the polishing solution of the invention. Malic acid was used instead of phosphoric acid. That is, the composition of the polishing solution comprises water, malic acid, lactic acid, BTA, imidazole, ammonium polyacrylate with a weight average molecular weight of 200,000 and aqueous hydrogen peroxide. As a result of conducting CMP under the same conditions as those in Example 1 by using the polishing solution, the polishing rate and the distribution thereof in the plane were substantially the same as the case of using phosphoric acid. On the other hand, the step between the copper or copper-based alloy and the tantalum barrier layer after CMP for the copper or copper-based alloy was 20 nm, which was reduced to about one-half compared with the polishing solution using phosphoric acid. Further, also in the case of using nitric acid, citric acid, tartaric acid, or malonic acid in addition to malic acid as a substitute for phosphoric acid, the polishing characteristics were favorable similarly to the result of using the malic acid.

### EXAMPLE 6

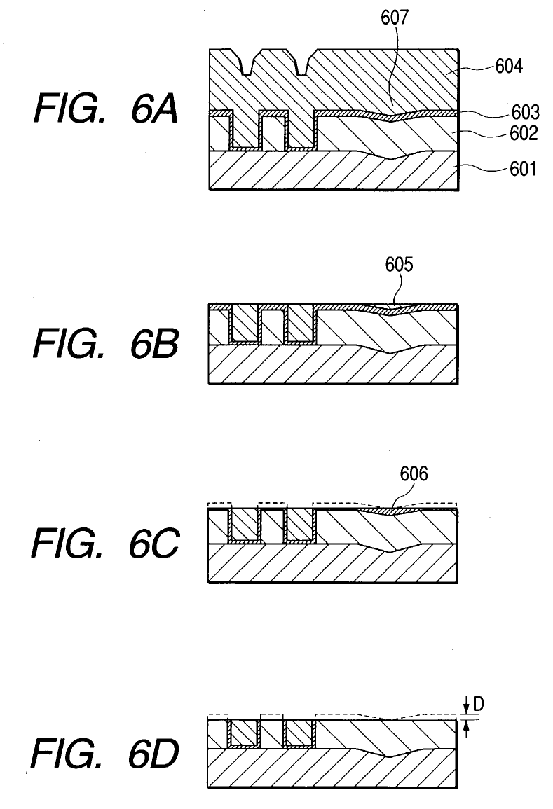

Application to the damascene method is to be described in details with reference FIG. 6. As schematically shown in FIG. 6A, an actual substrate to be polished 601 is a silicon wafer and various undulations or depressions 607 may sometimes be present on the surface thereof. For example, they are steps formed succeeding to the underlying element (not illustrated) formed with multi-layered wiring of copper or copper-based alloy, or depressions succeeding to wiring in the underlying layer (not illustrated). Such underlying steps can be planarized to 0.5 μm by conducting CMP to an insulation film 602 formed to a thickness, for example, of 0.6 μm of SiO₂ prior to the step of forming damascene wiring. However, this is not always sufficient to leave depressions 607 of various shapes such as having shallow and wide moderate cross section or comparatively fine and relatively deep cross section. A tantalum layer of 20 nm thickness as a barrier layer 603 and a copper or copper-based alloy layer 604 of 1 μm thickness are formed by known sputtering method and electric plating method. Accordingly, when the abrasive-free pressing solution shown in Example 1 of the invention was used in the first step CMP for the copper or copper-based alloy, since CMP was conducted at high accuracy, CMP residue 605 of the copper or copper-based alloy or CMP residue 606 of the barrier layer was formed in the portion of the depression 607 on the surface of an LSI substrate.

As one of the methods for avoiding the residue, the first step of CMP for the copper or copper-based alloy was conducted under the conditions capable of conducting CMP only for the copper or copper-based alloy at high selectivity and with high accuracy to form a shape as shown in FIG. 6B in which the copper or copper-based alloy residue 605 was present only in the depression 607 and the second step of CMP was conducted under the conditions capable of conducting CMP at the highest rate for the barrier film 603 but also capable of conducting CMP for the residual copper or copper-based alloy 605 and the barrier film at a constant CMP rate. According to this method, as shown in FIG. 6C, a state of completely removing the copper or copper-based alloy can be attained. The polishing solution, for example, formed by adding silica abrasive grains to the abrasive-free polishing solution of the invention and increasing the amount of the corrosion inhibitor such that the CMP rate is substantially equal for the barrier film and the copper or copper-based alloy film is preferred.

Then, as shown in FIG. 6D, a third step of CMP was conducted by using a polishing solution capable of conducting CMP for the barrier layer residue 606 and the insulation film 602 at a substantially same rate, with the CMP rate for the copper or copper-based alloy being one-half thereof, to obtain wiring of the copper or copper-based alloy of excellent planarity as shown in FIG. 6D. In this case, the thickness of the wiring of the copper or copper-based alloy is reduced by a depth corresponding to D of the initial depression 607. To reduce the amount of decrease, it is necessary to use a substrate to be polished excellent in the surface planarity, or sufficiently planarize the surface after forming underlying wiring or the elements below the wiring layer.

For simplification of the steps, the second and third CMP steps may be conducted simultaneously. In this case, it is preferred to use a polishing solution providing conditions of making the polishing rates identical as much as possible for the copper or copper-based alloy, the barrier film and the insulation film by controlling the abrasive grains and the concentration of the corrosion inhibitor.

In a case where the barrier layer is made of Ti or TiN, an abrasive-free polishing solution can be used. For example, an abrasive-free polishing solution comprising hydrogen peroxide and an aromatic nitro compound can be used. The aromatic nitro compound functions as an oxidizer for promoting the etching of the titanium compound. The protection film forming agent described above can be added optionally. The composition comprises 20% by weight of aqueous hydrogen peroxide, 10% by weight of nitro benzene sulfonic acid and 0.3% by weight of BTA. According to the polishing liquid, the polishing rate was 50 nm/min for TiN and 1 nm/min or less for the copper or copper-based alloy.

### EXAMPLE 7

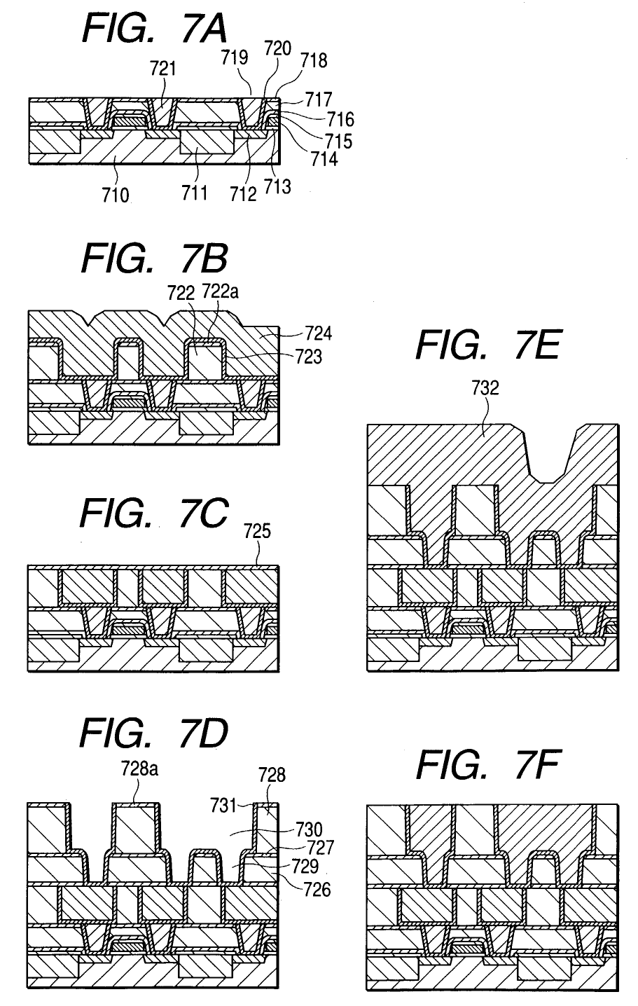

Application of the invention to formation of wiring on a semiconductor integrated circuit substrate including semiconductor devices is to be described with reference to FIG. 7. This example shows a case of forming a transistor as a device. In a case of a dynamic random access memory, since an additional step such as a step of forming a capacitor is incorporated to complicate the device forming step but the step after leading out electrodes from the device is substantially same.

The CMP apparatus and the abrasive-free polishing solution used in this example are the same as those in Example 1. The solution was supplied at a rate of 200 ml/min to a polishing platen. The sliding speed was 60 m/min and the CMP pressure was 200 g/cm^{2.} IC1000 made of foamed polyurethane resin was used for the polishing pad and the condition for the platen temperature during polishing used was 22° C. In this case, the polishing rate for the copper or copper-based alloy was about 460 nm/min.

In parallel, as shown in FIG. 7A, an inlaid insulation layer 711 for inter-device isolation was formed on the surface of a polished substrate 710 of 8 inch diameter containing p-type impurities. The surface was planarized by CMP using an alkaline polishing solution containing silica abrasive grains and ammonia. Then, n-type impurity diffusion layer 712 was formed by using ion implantation or heat treatment and a gate insulation film 713 was formed by a thermal oxidation method or the like. Then, a gate 714 comprising, for example, polycrystal silicon or a lamination film of a high melting metal and polycrystal silicon is fabricated and formed. A device protection film 715 comprising, for example, an SiO₂ film with addition of SiO₂ or phosphorus and an anti-contamination film 716 comprising, for example, an SiN film was deposited on the surface thereof. Further, after forming a planarization layer 717 comprising an SiO₂ (hereinafter referred to as p-SiO₂) film formed by a known plasma enhanced chemical vapor deposition (hereinafter referred to as PE-CVD method) by using monosilane as a starting material by a thickness of about 1.5 μm, it was planarized at the surface by scraping the thickness for about 0.8 μm by CMP for the insulation film using the alkaline silica abrasive-incorporated polishing solution. Further, the surface was covered with a second protection layer 718 made of SiN. Successively, a contact hole 719 for connection with a device was opened at a predetermined portion and a laminate film 720 of Ti and TiN both for adhesion and anti-contamination and a tungsten layer 721 were formed and the portions other than the hole were removed by polishing, to form a plug structure.

The lamination film 720 of titanium and titanium nitride was formed by a known reactive sputtering or plasma CVD method. Tungsten can be formed also by using the sputtering method or CVD method. The size of the contact hole 719 was about 0.2 μm or less in diameter and 0.5 to 0.8 μm in depth. The depth further increases to sometimes reach 1 μm or more, in a case of forming a device for the dynamic random access memory. The thickness of the lamination film 720 at a planar portion was about 50 nm. The thickness of the tungsten 721 was about 0.6 μm. This is because the contact hole is filled fully and the planarity of the film surface is improved to facilitate polishing of tungsten. To polish the lamination film of tungsten and titanium nitride, a silica abrasive-incorporated SSW-2000 (trade name of products manufactured by Cabot Co.) polishing solution mixed with hydrogen peroxide as an oxidizer was used as the polishing agent. The conditions described previously were used for other polishing conditions except for the polishing agent. Both of them were polished by using a same polishing platen (not illustrated) in the first polishing apparatus.

Then, as shown in FIG. 7B, a first interlevel insulation layer 722 comprising a silicone resin HSG2209S-R7 whose thickness is 0.5 μm and whose dielectric constant is 2.8 was formed, and a first cap layer 722a comprising a p-SiO₂ film was formed to 10 nm thickness. Wiring trenches were formed to the lamination of the first interlevel insulation layer 722 and the first cap layer 722a and a first barrier layer 723 of 50 nm thickness comprising titanium nitride and a first copper or copper-based alloy layer 724 were formed. Known reactive dry etching technique was used for the formation of the trenches. A second protection layer 718 comprising SiN also served as a etching stopper. The thickness of SiN was about 10 nm. The first copper or copper-based alloy layer 724 was formed in a copper or copper-based alloy of 0.7 μm thickness by applying a sputtering method and is subjected to a heat treatment at about 450° C. to be caused to flow, and then buried in the trenches.

Further, as shown in FIG. 7C, the first copper or copper-based alloy layer 724 was polished by using the abrasive-free polishing solution of Example 1 of the invention and using the second polishing apparatus (not illustrated) different from that used for polishing the tungsten 721 in the contact hole or the lamination film 720. This is to avoid contamination of the copper or copper-based alloy in the contact hole potion. Further, the first barrier layer 723 was polished by a polishing solution formed by adding 0.2% by weight of BTA to a solution mixture of a silica abrasive grain-incorporated polishing solution SSW-2000 (trade name of products manufactured by Cabot Co.) and hydrogen peroxide and a second polishing platen (not illustrated) of a second polishing apparatus. In the polishing for the first underlayer metal layer 723, IC1400 of a laminate structure comprising a foamed polyurethane resin for the upper surface and a soft resin layer for the lower layer (trade name of products manufactured by Rodel Co.) was used for the polishing pad. Since the polishing pad is somewhat soft, it is somewhat inferior to the IC1000 pad described above in view of the planarizing effect but it has a merit of causing less injuries due to polishing (polishing scratches) and capable of improving the yield of wiring. In a case where complicate structures such as active elements or wiring are present in the lower layer below the object to be polished as in this example, since the mechanical strength is lowered and tends to cause polishing scratches, the soft pad is used for avoiding the worry. A second contamination preventive film 725 comprising silicon nitride was formed on the surface after polishing by a plasma CVD method. The thickness of the layer was 20 nm.

In a case where various active elements are formed on the surface of the Si wafer 710 as in this example to form corresponding large and complicate surface steps, even when the planarization layer 717 has been polished, the surfaces for the first interlevel insulation layer 522 and the first cap layer 722a are not planarized sufficiently to sometimes leave shallow and wide depressions with a depth of about 5 nm and a width of about 5 μm corresponding to the width of the element. In a case where the characteristic of the abrasive-free polishing agent is excellent scarcely causing dishing or the like, CMP residue of the first copper or copper-based alloy layer 724 is sometimes formed also in such shallow depressions. In such a case, when the concentration of BTA added to the polishing agent comprising SSW-2000 and aqueous hydrogen peroxide is controlled to provide a characteristics capable of conducting CMP to some extent also for the first copper or copper-based alloy layer 724, even when some CMP residue is formed to the upper level metal layer, the CMP residue of the first copper or copper-based alloy layer 724 can also be removed stably upon CMP for the first barrier layer 723. After the completion of CMP, the surface was covered with a protection film 725 of the copper or copper-based alloy layer comprising a silicon nitride film of 20 nm thickness.

Then, a second interlevel insulation film 726 comprising SiLK whose thickness 0.7 μm is and whose dielectric constant is 2.7 was formed. Since SiLK was formed by a coating method and excellent also in the planarization effect, it also had an effect of eliminating the step formed, for example, in the polishing step for the first copper or copper-based alloy layer 724. Then, a p-SiO₂ film of 0.2 μm thickness was formed as a third protection film 727, an SiLK film of 0.7 μm thickness was formed as a third interlevel insulation film 728, and then a p-SiO₂ film of 10 nm thickness was formed thereon as a second cap film 728a. Then, the first via hole 729 and the second wiring trench 730 were formed by using known photolithography and reactive dry etching to expose the surface of the first copper or copper-based alloy layer 724. When such a trench pattern of the two step structure was formed, the third protection film 727 also served as an etching stopper. A titanium nitride film of 50 nm thickness was formed as a second barrier layer 731 in the thus formed trench of the two step structure by a plasma CVD method as shown in FIG. 7D.

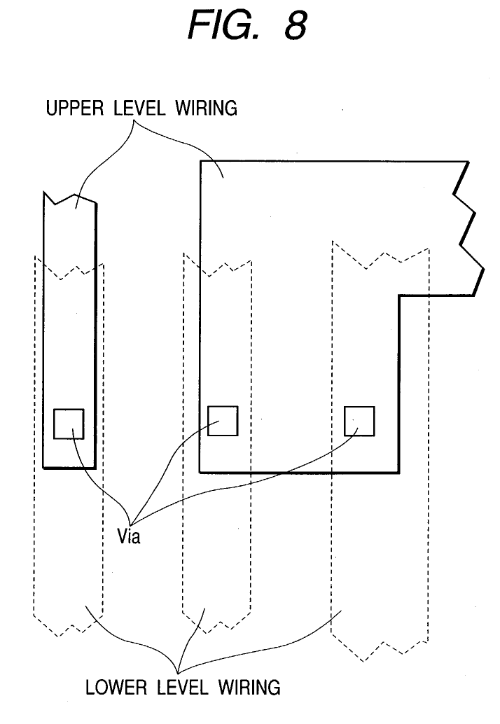

Further, as shown in FIG. 7E, a second copper or copper-based alloy layer 732 was formed to 1.6 μm thickness and buried by using known sputtering method and plating method. CMP was conducted for 2 min to the second copper or copper-based alloy layer 732 with other conditions such as the polishing pressure being identical with those in the case of the first copper or copper-based alloy layer 724 by using the abrasive-free polishing solution at high CMP rate shown in Example 3 of the invention. Since the abrasive-free CMP of the invention also provided uniform distribution of CMP rate within the plane, the copper or copper-based alloy could be removed over the entire Si wafer 710. Further, the second barrier layer 731 was polished by using the polishing agent using SSW-2000 and hydrogen peroxide with addition of BTA at a rate of 200 nm/min to form two layered wiring of the copper or copper-based alloy using a damascene method and a dual damascene method as shown in FIG. 7F. As described above, when a polishing method for the copper or copper-based alloy layer and the barrier layer for two stages was used, multi-layered wiring could be formed at a high yield while keeping favorable planarity on the surface of each of the insulation films and the metal layer. Further, FIG. 8 shows a plan view of a semiconductor whose cross section is shown in FIG. 7F. In FIG. 8, only the lower level wiring, the upper level wiring, and via holes are shown but devices such as transistors are not illustrated.

In this example, an example of forming dual wiring layers of the copper or copper-based alloy is shown but more multi-layered wiring of the copper or copper-based alloy, for example, of seven- or nine-layered structure can also be formed by substantially same procedures. However, as the number of wiring layers increases, undulations on the surface of the polished substrate 710 are also increased making it difficult to CMP for the copper or copper-based alloy or the barrier layer. Thus, it is preferred to properly insert the CMP step for the insulation film after forming the interlevel insulation film to ensure required planarity.

### EXAMPLE 8

In this example, to obtain a high polishing rate at low frictional force, a film of a copper or copper-based alloy was polished by using an abrasive-free polishing solution using phosphoric acid as a first etchant and lactic acid as a second etchant for dishing evaluation.

The composition of the polishing solution comprises 0.15% by volume of phosphoric acid as a first etching, 0.6% by volume of lactic acid as a second etchant, 0.2% by weight of BTA as a first corrosion inhibitor, 0.4% by weight of imidazole as a second inhibitor, 0.05% by volume of polyacrylic acid neutralized with ammonia as a surfactant, 30% by volume of hydrogen peroxide (H₂O₂ concentration: 30 wt %) and the balance of deionized water.

As a substrate to be polished, an SiO₂ film of 50 nm thickness was formed by a thermal oxidation method on the surface of a silicon wafer of 8 inch diameter, on which an SiO₂ film of 1 μm thickness was deposited by a PE-CVD method using a TEOS (tetraethoxysilane) gas as a starting material, and wiring trenches each of 500 nm depth and 0.25 to 20 μm width were formed by using known photolithography and reactive dry etching. A Ta film as a barrier layer of 40 nm thickness was formed by a sputtering method and a copper film of 800 nm thickness was formed on the substrate including the inside of the wiring trenches by using a sputtering method and an electrolytic plating method.

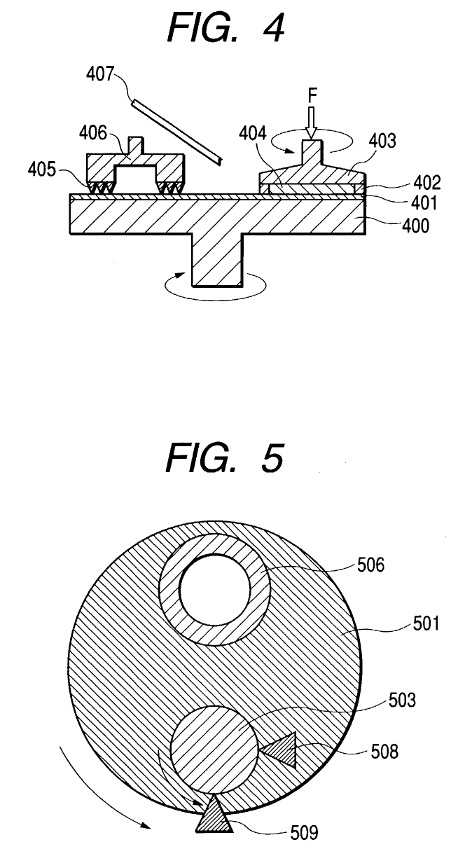

Then, CMP was conducted for the copper film by using the polishing solution described above. The CMP apparatus shown in FIG. 4 was used and IC1000 (trade name of products manufactured by Rodel Co.) made of a foamed polyurethane resin was used for the polishing pad. The CMP pressure was 200 g/cm², the sliding speed was 60 m/min and the supply amount of the polishing solution was 200 ml/min. 30% excess polishing was conducted in CMP for the copper film. The required polishing time was about 2 min.

As a result of measuring dishing for the wiring trench portions in the polished substrate by the method described above, the dishing was 30 nm or less in a case for the wiring width of 1 μm or less and 50 nm for the portion of the wiring width of 20 μm. Usually, dishing is desirably kept to 10% or less and, preferably, 5% or less based on the thickness of the wiring, and the depth of the dishing described above is a limit value for satisfying the requirement in a case where the thickness of the copper wiring is 500 nm as in this example.

In view of the above, with an aim of reducing the dishing further, lowering of the etching rate of the polishing solution to the copper film was attempted. In this example, experiment was conducted in a case of increasing the concentration of imidazole.

In the dishing solution of Example 1, the etching rate for the copper film was 3 nm/min at the imidazole concentration of 0.4% by weight. Then, when the concentration of imidazole was increased up to 0.55% by weight. The etching rate was reduced to one-half, that is, 1.6 nm/min. As a result of conducting CMP by using the polishing solution, the polishing rate for the copper film was reduced to 30 nm/min or less. It is considered that the frictional force was decreased extremely due to excess increase in the concentration of imidazole thereby causing slipping on the surface to be polished.

Then, an experiment was conducted to a case of lowering the concentration of phosphoric acid or lactic acid as the etchant for the etching solution of Example 1. Characteristics when the phosphoric acid was reduced to 0.08% by volume and the lactic acid to 0.45% by volume were examined. At first, for the polishing rate, a relatively high value was obtained as about 400 nm/min for the etching solution in which phosphoric acid was reduced to 0.08% by volume, and a relatively value as high as about 300 nm/min was obtained for the polishing solution in which lactic acid was decreased to 0.45% by volume. However, the dishing depth was substantially the same as the conventional case in each of the polishing solutions in which the addition amount of phosphoric acid or lactic acid was decreased. Further, it has been found that when the addition amount of phosphoric acid or lactic acid was decreased, practical polishing characteristics could no more be obtained.

As has been described above, the polishing solution using phosphoric acid as the first etchant and lactic acid as the second etchant is effective for increasing the etching rate in which the amount of dishing was about equal with that in Example 1.

### EXAMPLE 9

In this example, a relation between the acidity of an acid used as the etchant and the dishing characteristic was studied. For the acid as the etchant, six types of acids, namely, phosphoric acid, lactic acid, malic acid, oxalic acid, malonic acid and tartaric acid were examined. The etching rate for the copper film, when each of the acids at a same concentration was added to a solution comprising 0.2% by weight of BTA, 30% by volume of hydrogen peroxide and the balance of deionized water, was used as the acidity of the acid. As a result, it has been found the acidity of that oxalic acid is most strong, followed that of malonic acid, tartaric acid, phosphoric acid, malic acid and lactic acid in this order.

Then, malic acid and lactic acid as the acid weaker than phosphoric acid were examined. A solution formed by adding malic acid or lactic acid to a solution having a composition comprising 0.2% by weight of BTA as a corrosion inhibitor, 0.05% by volume of polyacrylic acid neutralized with ammonia as a surfactant, 30% by volume of hydrogen peroxide and the balance of deionized water such that the etching rate for the copper film was 3 nm/min or less was used. As a result of conducting CMP for the copper film under the same polishing conditions as those in Example 8 by using the CMP apparatus shown in FIG. 4, the etching rate was lowered to about 150 nm in a case of adding malic acid and 30 nm/min or less in a case of adding lactic acid and no practical polishing characteristic could be obtained. This is a result of using BTA alone as a corrosion inhibitor and, when imidazole was further added as a second corrosion inhibitor, the polishing rate was further lowered. It is estimated that imidazole added as the second corrosion inhibitor developed an effect of lowering the coefficient of dynamic friction.

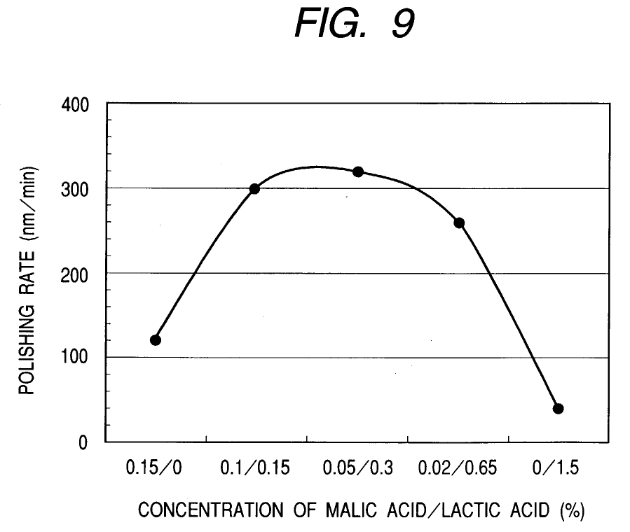

Then, use of plurality types of organic acids as the etchant was examined. In this example, malic acid was used as the first etchant and lactic acid was used as the second etchant. FIG. 9 shows the change of the polishing rate for the copper film when malic acid and lactic acid were added such that the etching rate for the copper film was 3 nm/min or less, to a composition comprising 0.2% by weight of BTA as a first corrosion inhibitor, 0.04% by weight of imidazole as a second corrosion inhibitor, 0.05% by volume of a polyacrylic acid as a surfactant, 30% by volume of hydrogen peroxide and the balance of deionized water. As described above, while no sufficient polishing rate was obtained in a case of using malic acid or lactic acid alone as the etchant, a polishing rate exceeding 300 nm/min was obtained by using both of them in combination.

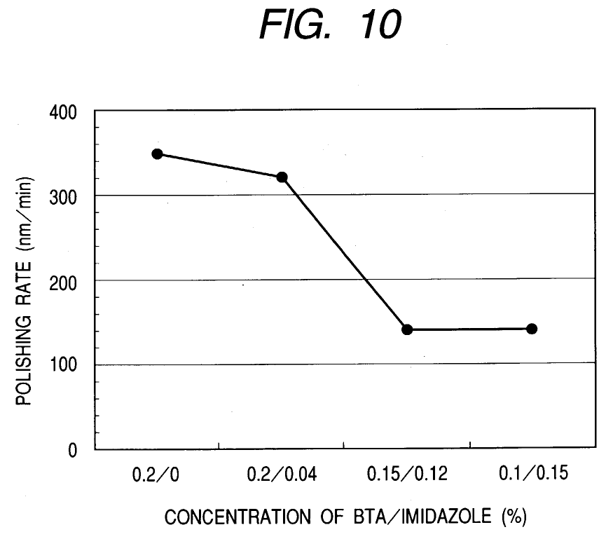

Then, optimization of the imidazole concentration is to be described. FIG. 10 shows the change of the polishing rate to the copper film when BTA and imidazole were added to a composition comprising 0.05% by weight of malic acid as a first etchant, 0.3% by volume of lactic acid as a second etchant, 0.05% by volume of polyacrylic acid as a surfactant, 30% by volume of hydrogen peroxide and the balance of deionized water such that the etching rate for the copper film was 3 nm/min or less. Since the polishing rate is lowered along with lowering of the coefficient of dynamic friction when the imidazole concentration is excessively high, it is further preferred to have a concentration of 0.05% by weight or less.

As has been described above, imidazole when used in combined with BTA has an effect of decreasing the dynamic friction during polishing in addition to the effect of increasing the corrosion inhibiting effect. Accordingly, in a case of using conditions at which the dynamic friction is extremely lowered during polishing, for example, where the polishing speed is high or CMP pressure is low or the supply amount of the polishing solution is small, BTA can be used alone as a corrosion inhibitor without adding imidazole.

### EXAMPLE 10

In this example, a case of using malic acid and lactic acid in combination as the etchant of the polishing solution is to be described.

A polishing solution formed by adding malic acid and lactic acid to a composition comprising 0.2% by weight of BTA as a first corrosion inhibitor, 0.04% by weight of imidazole as a second corrosion inhibitor, 0.05% by volume of polyacrylic acid as a surfactant, 30% by volume of hydrogen peroxide and the balance of deionized water such that the etching rate for the copper film was 3 nm/min or less was used as the polishing solution.

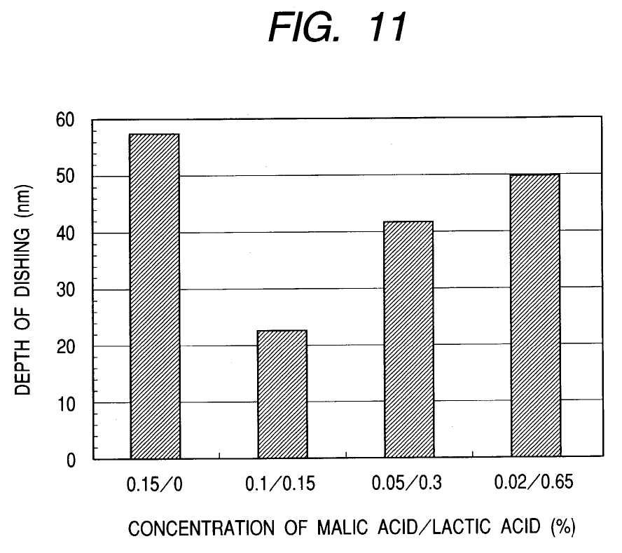

FIG. 11 shows a result of measurement for the portion of 20 μm wiring width after conducting CMP for the substrate to be polished identical with that used in Example 8. It has been found that dishing was smaller in the case of using malic acid and lactic acid than in the case of using only malic acid for the etchant and, further, smaller amount for the total of malic acid and lactic acid is desirable for reducing the dishing so long as the polishing rate does not deteriorate greatly.

As has been described above, the polishing solution using malic acid and lactic acid for the etchant is effective in improving the polishing rate and decreasing the dishing of copper or copper-based alloy in wiring trenches.

### EXAMPLE 11

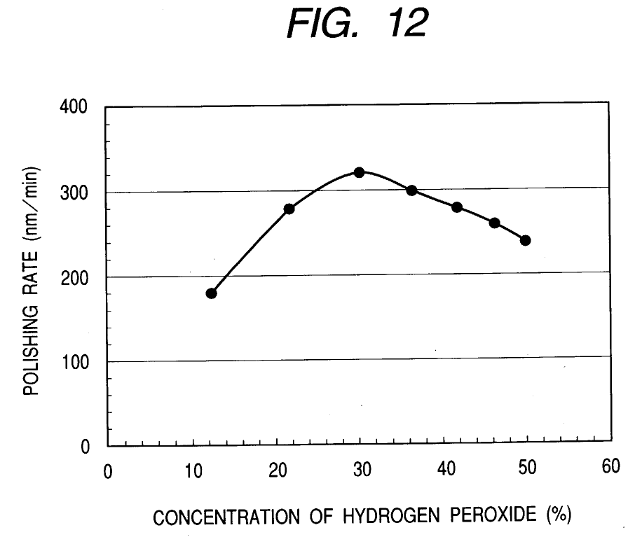

In this example, optimization for the concentration of hydrogen peroxide used for the polishing solution is to be described. A solution comprising 0.1% by weight of malic acid as a first etchant, 0.15% by volume of lactic acid as a second etchant, 0.2% by weight of BTA as a first corrosion inhibitor, 0.04% by weight of imidazole as a second corrosion inhibitor, and 0.05% by volume of a polyacrylic acid as a surfactant was prepared. FIG. 12 shows a change of the polishing rate for the copper film when the concentration of aqueous hydrogen peroxide (H₂O₂ concentration: 30 wt %) added thereto was changed. The polishing rate is greatest at the concentration of aqueous hydrogen peroxide of 30% by volume and the etching rate lowers gradually even if the concentration of hydrogen peroxide is lower or higher.

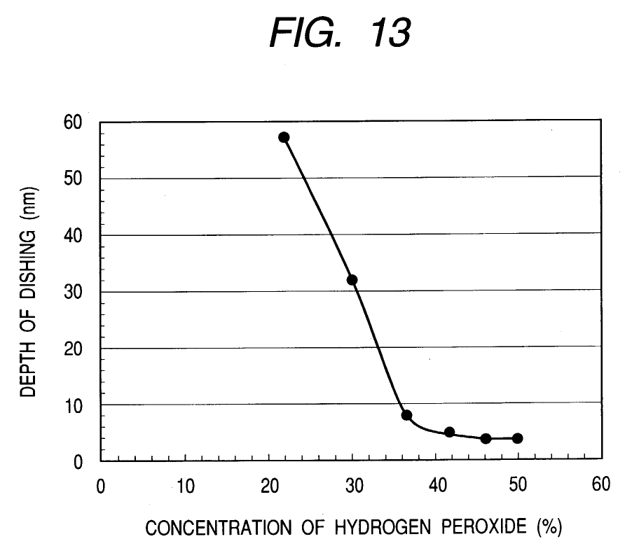

FIG. 13 shows a depth of dishing of the copper film after conducting CMP to a substrate to be polished identical with that used in Example 8 by using a polishing solution similar to that of FIG. 12. Dishing is smaller as the concentration of hydrogen peroxide is higher and the depth of dishing is lowered to 10 nm or less by increasing the concentration of hydrogen peroxide to 35% by volume or more. The depth of dishing is a value capable of efficiently coping with microfabrication of the wiring width and wiring thickness which will be proceeded further in the feature. As the concentration of hydrogen peroxide increases, the etching rate for the copper or the copper-based alloy is lowered and, further, the coefficient of dynamic friction is also lowered and it is estimated that they caused further reduction of dishing.

In this example, an abrasive-free polishing solution is shown as an example but further higher polishing rate can be obtained while suppressing dishing lower by adding a smaller amount of abrasive grains to the polishing solution of this example.

Further, in a case where thick a copper or copper-based alloy film of 1 μm or more is formed on the substrate to be polished formed with wiring trenches, throughput can be improved by conducting CMP for one-half or more of a copper or copper-based alloy film by using the polishing solution capable of obtaining higher polishing rate than in this example as a first polishing solution and then conducting CMP for remaining portion by using the polishing solution of this example as a second polishing solution. As the first polishing solution, it is possible to use the abrasive-free polishing solution using phosphoric acid and lactic acid for the etchant as shown in Example 4, as well as commercially available abrasive-incorporated polishing solutions. In a case of using the abrasive-incorporated polishing solution as the first polishing solution, it is preferred to clean the substrate to be polished sufficiently before conducting CMP by using the polishing solution of this example.

The present invention provides a novel abrasive-free polishing solution using plural types of corrosion inhibitors, particularly, BTA and imadazole in combination. This can attain CMP for copper or copper-based alloys with remarkably lower friction force than usual, that is, with a coefficient of dynamic friction of 0.4 or less. By using the polishing solution, it is possible to prevent delamination also in CMP for copper or copper-based alloy films formed of a low dielectric constant insulation film whose specific dielectric constant is 3.0 or less. Further, the present invention also enables CMP at high speed comparable with that using the abrasive-incorporated polishing solution which was difficult to attain by the conventional abrasive-free polishing solution. Further, the present invention greatly decreases the friction force just after starting CMP and more stably prevents delamination during CMP for a copper or copper-based alloy on a low dielectric constant material.

What is claimed is:

1. A method of manufacturing a semiconductor device in which at least a portion of a metal film is removed, the metal film being formed on an insulation film containing at least carbon or silicon, comprising the steps of:
preparing a metal film comprising copper or copper-based alloy, a polishing pad made of a polymeric resin and a polishing solution whose coefficient of dynamic friction during polishing is less than 0.5; and
polishing the metal film by using the polishing pad.

2. A method of manufacturing a semiconductor device in which copper or copper-based alloy formed on an insulation film whose specific dielectric constant is 3 or less is rubbed and polished using a polishing pad made of a polymeric resin,
wherein polishing is conducted by using a polishing solution containing a metal oxidizing material, a metal oxide dissolving material, benzotriazole and imidazole.

3. A method of manufacturing a semiconductor device in which a semiconductor substrate of 8 inch or more having copper or copper-based alloy on the surface formed on an insulation film whose specific dielectric constant is 3 or less is rubbed and polished using a polishing pad made of a polymeric resin,
wherein polishing is conducted by using a polishing solution containing a metal oxidizing material, a metal oxide dissolving material, benzotriazole and imidazole.

4. A method of manufacturing a semiconductor device as defined in any one of claims 1 to 3, wherein the frictional resistance upon polishing the copper or copper-based alloy is 100 g/cm² or less.

5. A method of manufacturing a semiconductor device as defined in any one of claims 1 to 4, wherein the insulation film comprises a material containing at least carbon and hydrogen, a specific dielectric constant of the material being 3 or less.

6. A method of manufacturing a semiconductor device as defined in any one of claims 1 to 4, wherein the insulation film comprises a material containing at least carbon, hydrogen and silicon, a specific dielectric constant of the insulation film being 3 or less.

7. A method of manufacturing a semiconductor device as defined in any one of claims 1 to 6, wherein the polishing solution comprises at least one member selected from the group consisting of an oxidizing material, an inorganic acid and an organic acid; at least two members selected from the group consisting of corrosion inhibitors comprising benzotriazole or derivatives thereof, imidazole or derivatives thereof, benzoimidazole or derivatives thereof, naphthotriazole, and benzothiazole or derivatives thereof; and water.

8. A method of manufacturing a semiconductor device as defined in claim 7, wherein the organic acid is at least one or plurality of members selected from malic acid, oxalic acid, malonic acid, polyacrylic acid and lactic acid.

9. A method of manufacturing a semiconductor device as defined in any one of claims 1 to 6, wherein, at the start of polishing, a complex salt of copper or copper-based alloy is mixed with the polishing solution for polishing, and then polishing is conducted successively without mixing the complex salt of the copper or copper-based alloy.

10. A method of manufacturing a semiconductor device as defined in any one of claims 7 to 9, wherein the inorganic acid is one or both of phosphoric acid and amidosulfonic acid.

11. A method of manufacturing a semiconductor device as defined in any one of claims 7 to 10, wherein the corrosion inhibitor contains two ingredients of benzotriazole and imidazole.

12. A method of manufacturing a semiconductor device as defined in claim 11, wherein the concentration of benzotriazole is within a range from 0.05 to 2.0% by weight.

13. A method of manufacturing a semiconductor device as defined in claim 11, wherein the concentration of imidazole is within a range from 0.05 to 3.0% by weight.

14. A method of manufacturing a semiconductor device as defined in any one of claims 7 to 13, wherein the polyacrylic acid, or ammonium polyacrylate, or amine polyacrylate is further added to the polishing solution as a surfactant and used.

15. A method of manufacturing a semiconductor device as defined in claim 14, wherein the concentration of the polyacrylic acid is within a range from 0.01% by volume to 2.0% by volume.

16. A method of manufacturing a semiconductor device as defined in any one of claims 1 to 15, wherein the polishing solution contains polishing abrasive grains of alumina or silica.

17. A method of manufacturing a semiconductor device, wherein, when removing a barrier metal film formed on an insulation film formed and fabricated with trenches or holes and at least a portion of a copper or copper-based alloy film formed on the surface of the barrier film, the surface of the copper or copper-based alloy film is mechanically polished by using a first polishing solution containing aqueous hydrogen peroxide, phosphoric acid, lactic acid and a protection film forming agent, and then the surface of the copper or copper-based alloy film, or the surface of the barrier metal film, or the surface of the insulation film is mechanically polished by using a second polishing solution containing polishing abrasive grains.

18. A method of manufacturing a semiconductor device including the steps of:
preparing a substrate having a wiring layer;
forming an insulation film having openings for exposing the wiring layer;
forming a barrier metal film on the substrate formed with the insulation film and further forming a copper or copper-based alloy film on the surface of the barrier metal;
mechanically polishing the surface of the copper or copper-based alloy film by using a first polishing solution containing an oxidizing substance, phosphoric acid, lactic acid and a protection film forming agent, thereby exposing the barrier metal film;
mechanically polishing the surface of the copper or copper-based alloy film or the surface of the barrier metal film by using a second polishing solution containing an oxidizing substance, phosphoric acid, lactic acid, a protection film forming agent, water and abrasive grains, thereby exposing the surface of the insulation film;
cleaning the substrate; and
drying the cleaned substrate.

19. A method of manufacturing a semiconductor device as defined in claim 18, wherein the concentration of the protection film forming agent contained in the second polishing solution is higher than the concentration of the protection film forming agent contained in the first polishing solution.

20. A method of manufacturing a semiconductor device in which a TiN film formed on an insulation film and at least a portion of a copper or copper-based alloy film formed on the surface of the TiN are removed,
wherein the surface of the copper or copper-based alloy film is mechanically polished by using a first polishing solution containing aqueous hydrogen peroxide, phosphoric acid, lactic acid and a protection film forming agent; and
the surface of the copper or copper-based alloy film, or the surface of the TiN film, or the surface of the insulation film is mechanically polished by using a second polishing solution containing aqueous hydrogen peroxide and an aromatic nitro compound.

21. A method of manufacturing a semiconductor device in which a barrier metal film on an insulation film formed and fabricated with trenches or holes is formed, a copper or copper-based alloy film is formed on the barrier metal film, and at least a portion of the copper or copper-based alloy film is removed,
the copper or copper-based alloy film is mechanically polished by using a polishing solution containing at least malic acid, lactic acid, benzotriazole, a surfactant and an oxidizer, thereby removing the copper or copper-based alloy film.

22. A method of manufacturing a semiconductor device in which a barrier metal film on an insulation film formed and fabricated with trenches or holes is formed, a copper or copper-based alloy film is formed on the barrier metal film, and at least a portion of the copper or copper-based alloy film is removed,
wherein the copper or copper-based alloy film is mechanically polished by using a polishing solution containing at least malic acid, lactic acid, benzotriazole, imidazole, a surfactant and an oxidizer, thereby removing the copper or copper-based alloy film.

23. A method of manufacturing a semiconductor device as defined in claim 22, wherein the concentration of imidazole is 0.05% by weight or less.

24. A method of manufacturing a semiconductor device as defined in any one of claims 21 to 23, wherein the oxidizer is hydrogen peroxide and the concentration of hydrogen peroxide is 35% by volume or more.

25. A method of manufacturing a semiconductor device as defined in any one of claims 21 to 24, wherein the surfactant is polyacrylic acid or ammonium polyacrylate or amine polyacrylate.
